(19) United States
(12) Patent Application Publication
(10) Pub. No.: US 2024/0306300 A1
(43) Pub. Date: Sep. 12, 2024

(54) Flexible Circuit Board, Circuit Board Assembly, and Electronic Device

(71) Applicant: HONOR DEVICE CO., LTD., Guangdong (CN)

(72) Inventors: Jianqiang Guo, Shenzhen (CN); Wenjun Luo, Shenzhen (CN); Mingchuan Li, Shenzhen (CN)

(21) Appl. No.: 18/000,891

(22) PCT Filed: Aug. 18, 2022
(86) PCT No.: PCT/CN2022/113314

§ 371 Date: Dec. 6, 2022

(30) Foreign Application Priority Data
Sep. 27, 2021 (CN) 202111137418.3

(51) Int. Cl. H05K 1/11; H01R 12/62

(52) U.S. Cl. CPC H05K 1/118; H01R 12/62; H05K 2201/09481; H05K 2201/09572; H05K 2201/09854

(57) ABSTRACT

A flexible circuit board, a circuit board assembly, and an electronic device are provided. The flexible circuit board includes at least a flexible dielectric layer and a first connection metal layer. The flexible dielectric layer includes a through hole extending along a thickness direction of the flexible dielectric layer. The through hole includes a middle basic hole and outer auxiliary holes. Two or more outer auxiliary holes are distributed and arranged along a circumferential direction of the middle basic hole. The middle basic hole is in communication with the two or more outer auxiliary holes. The first connection metal layer is arranged on an inner wall of the through hole and is connected to the flexible dielectric layer. The first connection metal layer includes a middle channel extending along a thickness direction.

### CROSS-REFERENCE TO RELATED APPLICATIONS

This application is a national stage of International Application No. PCT/CN2022/113314, filed on Aug. 18, 2022, which claims priority to Chinese Patent Application No. 202111137418.3, filed on Sep. 27, 2021. The disclosures of both of the aforementioned applications are hereby incorporated by reference in their entireties.

### TECHNICAL FIELD

Embodiments of this application relate to the field of terminal technologies, and in particular, to a flexible circuit board, a circuit board assembly, and an electronic device.

### BACKGROUND

With the explosive growth of electronic devices such as mobile phones, tablet computers (portable equipment, PAD), and notebook computers, the electric devices increasingly become one of the necessities of modern people's lives, and therefore, are increasingly important in various scenarios such as modern life and working contact. A printed circuit board (Printed Circuit Board, PCB) and a flexible circuit board (Flexible Printed Circuit, FPC) are usually arranged in an electronic device. In some cases, the printed circuit board and the flexible circuit board need to be connected to each other for an electrical connection. For example, the printed circuit board and the flexible circuit board are connected to each other by a board-to-board connector (board to board, BTB). A board-to-board connector is arranged on each of the printed circuit board and the flexible circuit board. The printed circuit board and flexible circuit board are connected to each other through mutual plugging of the two board-to-board connectors. However, because the size of the board-to-board connector itself is relatively large, the board-to-board connector needs to occupy a relatively large mounting space, which is not conducive to the miniaturization of electronic devices. To replace the board-to-board connector, the flexible circuit board and the printed circuit board are soldered and connected together by using a flexible circuit board-printed circuit board inter-board connection (FPC on board (FOB)) technology. However, in a process of assembling the flexible circuit board and the printed circuit board that have been soldered, the flexible circuit board is prone to damage, for example, the flexible circuit board is torn at the soldering place, resulting in the failure and obsolete of the flexible circuit board.

### SUMMARY

Embodiments of this application provide a flexible circuit board, a circuit board assembly, and an electronic device, to reduce occurrence of tearing of a flexible circuit board at a soldering place.

A first aspect of this application provides a flexible circuit board. The flexible circuit board includes at least a flexible dielectric layer and a first connection metal layer. The flexible dielectric layer includes a through hole extending along a thickness direction of the flexible dielectric layer. The through hole includes a middle basic hole and outer auxiliary holes. Two or more outer auxiliary holes are distributed and arranged along a circumferential direction of the middle basic hole. The middle basic hole is in communication with the two or more outer auxiliary holes. The first connection metal layer is arranged on an inner wall of the through hole and is connected to the flexible dielectric layer. The first connection metal layer includes a middle channel extending along a thickness direction.

The flexible circuit board according to the embodiments of this application includes a flexible dielectric layer and a first connection metal layer. The flexible dielectric layer is provided with a through hole. The through hole includes a middle basic hole and outer auxiliary holes. Compared with an embodiment in the related art in which the through hole is a single circular hole, since the two or more outer auxiliary holes are arranged along the circumferential direction of the middle basic hole, a shape of the through hole is different from a shape of a circular hole. In this application, a manner in which the through hole is arranged as the outer auxiliary holes and the middle basic hole can increase the contact area between the first connection metal layer and the flexible dielectric layer relatively in the bounded region, which, therefore, is beneficial to increasing the bonding force between the first connection metal layer and the flexible dielectric layer. Therefore, in the embodiments of this application, the bonding force between the first connection metal layer and the flexible dielectric layer is greater than the bonding force between the first connection metal layer and the flexible dielectric layer when the through hole is a circular hole, so that a joint between the flexible dielectric layer and the first connection metal layer can bear a larger tensile force. In the embodiments of this application, the flexible circuit board is connected to the printed circuit board, and when the flexible dielectric layer is subjected to a tensile force during assembly, the flexible dielectric layer and the first connection metal layer are unlikely to be separated, thereby helping to reduce the possibility that the flexible dielectric layer and the first connection metal layer are disconnected and torn.

In a possible implementation, two or more outer auxiliary holes are evenly distributed along the circumferential direction of the middle basic hole, so that the overall shape of the through hole can be guaranteed to be regular, which is beneficial to improving the force balance of the connection region between the inner wall of the through hole and the first connection metal layer, thereby ensuring the stability of the connection between the inner wall of the through hole and the first connection metal layer.

In a possible implementation, an axis of the outer auxiliary hole and an axis of the middle basic hole are parallel to each other, so that extension directions of the outer auxiliary hole and the middle basic hole are the same, leading to easy machining and manufacturing.

In a possible implementation, the outer auxiliary hole and the middle basic hole are both circular holes, so that they can be easily machined and manufactured through laser ablation or mechanical drilling, thereby reducing possibility that high machining and manufacturing difficulty caused by an irregular shape of the through hole results in a low yield of the flexible dielectric layer.

In a possible implementation, along the thickness direction, orthographic projections of the outer auxiliary holes and an orthographic projection of the middle basic hole intersect to form an intersection point P1, an intersection point P2, an intersection point P3, and an intersection point P4. The axis of the middle basic hole is located inside a region bounded by connecting lines between the intersection point P1, the intersection point P2, the intersection point P3, and the intersection point P4. The axes of the outer auxiliary holes are located outside the region bounded by the connecting lines between the intersection point P1, the intersection point P2, the intersection point P3, and the intersection point P4.

In a possible implementation, the connecting line between the intersection point P1 and the intersection point P3 and the connecting line between the intersection point P2 and the intersection point P4 intersect and have an angle ranging from 15° to 135°.

In a possible implementation, the two outer auxiliary holes are respectively located on two sides of the middle basic hole. The outer auxiliary holes are in communication with the middle basic hole. Axes of the two outer auxiliary holes and an axis of the middle basic hole are all located in the same plane.

In a possible implementation, four outer auxiliary holes are arranged around the axis of the middle basic hole. An inner wall of a through hole formed by four outer auxiliary holes and one middle basic hole has a larger area, so that a contact area between the first connection metal layer and the inner wall of the through hole is further increased, which is beneficial to further increasing the bonding force between the first connection metal layer and the inner wall of the through hole.

In a possible implementation, along the thickness direction, orthographic projections of the outer auxiliary holes and an orthographic projection of the middle basic hole intersect to form an intersection point P1, an intersection point P2, and an intersection point P3. The axis of the middle basic hole is located inside a region bounded by connecting lines between the intersection point P1, the intersection point P2, and the intersection point P3. The axes of the outer auxiliary holes are located outside the region bounded by the connecting lines between the intersection point P1, the intersection point P2, and the intersection point P3.

In a possible implementation, an angle between the connecting line between the intersection point P1 and the intersection point P2 and the connecting line between the intersection point P2 and the intersection point P3 ranges from 15° to 90°.

In a possible implementation, three outer auxiliary holes are arranged around the axis of the middle basic hole.

In a possible implementation, diameters of the outer auxiliary holes are greater than a diameter of the middle basic hole.

In a possible implementation, the diameters of the outer auxiliary holes are equal. The diameters of the outer auxiliary holes are 1.3 times the diameter of the middle basic hole.

In a possible implementation, diameters of the outer auxiliary holes are less than a diameter of the middle basic hole.

In a possible implementation, the diameters of the outer auxiliary holes are equal. The diameters of the outer auxiliary holes are 0.8 times the diameter of the middle basic hole.

In a possible implementation, the flexible circuit board further includes a second connection metal layer and a third connection metal layer. Along the thickness direction, the second connection metal layer and the third connection metal layer are respectively arranged on two sides of the flexible dielectric layer. The second connection metal layer and the third connection metal layer are respectively connected to the first connection metal layer. The second connection metal layer includes a first via in communication with the middle channel. The third connection metal layer includes a second via in communication with the middle channel. The second connection metal layer and the third connection metal layer are respectively connected to the flexible dielectric layer, which, therefore, is beneficial to further increasing the bonding force between the flexible dielectric layer and the solder pin.

In a possible implementation, the flexible dielectric layer includes two insulation substrates. The through hole runs through the two insulation substrates. The flexible circuit board further includes a fourth connection metal layer. The fourth connection metal layer is connected to the first connection metal layer, and the fourth connection metal layer is arranged between the two insulation substrates.

A second aspect of the embodiments of this application provides a circuit board assembly. The circuit board assembly includes at least: a printed circuit board and a flexible circuit board. The printed circuit board includes a pad. The flexible circuit board includes at least a flexible dielectric layer and a first connection metal layer. The flexible dielectric layer includes a through hole extending along a thickness direction of the flexible dielectric layer. The through hole includes a middle basic hole and outer auxiliary holes. Two or more outer auxiliary holes are distributed and arranged along a circumferential direction of the middle basic hole. The middle basic hole is in communication with the two or more outer auxiliary holes. The first connection metal layer is arranged on an inner wall of the through hole and is connected to the flexible dielectric layer. The first connection metal layer includes a middle channel extending along a thickness direction. The pad and the first connection metal layer are soldered by a solder joint, and a part of the solder joint is filled in the middle channel.

In a possible implementation, two or more outer auxiliary holes are evenly distributed along the circumferential direction of the middle basic hole, so that the overall shape of the through hole can be guaranteed to be regular, which is beneficial to improving the force balance of the connection region between the inner wall of the through hole and the first connection metal layer, thereby ensuring the stability of the connection between the inner wall of the through hole and the first connection metal layer.

In a possible implementation, an axis of the outer auxiliary hole and an axis of the middle basic hole are parallel to each other, so that extension directions of the outer auxiliary hole and the middle basic hole are the same, leading to easy machining and manufacturing.

In a possible implementation, the outer auxiliary hole and the middle basic hole are both circular holes, so that they can be easily machined and manufactured through laser ablation or mechanical drilling, thereby reducing possibility that high machining and manufacturing difficulty caused by an irregular shape of the through hole results in a low yield of the flexible dielectric layer.

In a possible implementation, along the thickness direction, orthographic projections of the outer auxiliary holes and an orthographic projection of the middle basic hole intersect to form an intersection point P1, an intersection point P2, an intersection point P3, and an intersection point P4. The axis of the middle basic hole is located inside a region bounded by connecting lines between the intersection point P1, the intersection point P2, the intersection point P3, and the intersection point P4. The axes of the outer auxiliary holes are located outside the region bounded by the connecting lines between the intersection point P1, the intersection point P2, the intersection point P3, and the intersection point P4.

In a possible implementation, the connecting line between the intersection point P1 and the intersection point P3 and the connecting line between the intersection point P2 and the intersection point P4 intersect and have an angle ranging from 15° to 135°.

In a possible implementation, the two outer auxiliary holes are respectively located on two sides of the middle basic hole. The outer auxiliary holes are in communication with the middle basic hole. Axes of the two outer auxiliary holes and an axis of the middle basic hole are all located in the same plane.

In a possible implementation, four outer auxiliary holes are arranged around the axis of the middle basic hole. An inner wall of a through hole formed by four outer auxiliary holes and one middle basic hole has a larger area, so that a contact area between the first connection metal layer and the inner wall of the through hole is further increased, which is beneficial to further increasing the bonding force between the first connection metal layer and the inner wall of the through hole.

In a possible implementation, along the thickness direction, orthographic projections of the outer auxiliary holes and an orthographic projection of the middle basic hole intersect to form an intersection point P1, an intersection point P2, and an intersection point P3. The axis of the middle basic hole is located inside a region bounded by connecting lines between the intersection point P1, the intersection point P2, and the intersection point P3. The axes of the outer auxiliary holes are located outside the region bounded by the connecting lines between the intersection point P1, the intersection point P2, and the intersection point P3.

In a possible implementation, an angle between the connecting line between the intersection point P1 and the intersection point P2 and the connecting line between the intersection point P2 and the intersection point P3 ranges from 15° to 90°.

In a possible implementation, three outer auxiliary holes are arranged around the axis of the middle basic hole.

In a possible implementation, diameters of the outer auxiliary holes are greater than a diameter of the middle basic hole.

In a possible implementation, the diameters of the outer auxiliary holes are equal. The diameters of the outer auxiliary holes are 1.3 times the diameter of the middle basic hole.

In a possible implementation, diameters of the outer auxiliary holes are less than a diameter of the middle basic hole.

In a possible implementation, the diameters of the outer auxiliary holes are equal. The diameters of the outer auxiliary holes are 0.8 times the diameter of the middle basic hole.

In a possible implementation, the flexible circuit board further includes a second connection metal layer and a third connection metal layer. Along the thickness direction, the second connection metal layer and the third connection metal layer are respectively arranged on two sides of the flexible dielectric layer. The second connection metal layer and the third connection metal layer are respectively connected to the first connection metal layer. The second connection metal layer includes a first via in communication with the middle channel. The third connection metal layer includes a second via in communication with the middle channel. The second connection metal layer and the third connection metal layer are respectively connected to the flexible dielectric layer, which, therefore, is beneficial to further increasing the bonding force between the flexible dielectric layer and the solder pin.

In a possible implementation, the flexible dielectric layer includes two insulation substrates. The through hole runs through the two insulation substrates. The flexible circuit board further includes a fourth connection metal layer. The fourth connection metal layer is connected to the first connection metal layer, and the fourth connection metal layer is arranged between the two insulation substrates.

A third aspect of the embodiments of this application provides an electronic device. The electronic device includes at least the circuit board assembly described above. The circuit board assembly includes at least: a printed circuit board and a flexible circuit board. The printed circuit board includes a pad. The flexible circuit board includes at least a flexible dielectric layer and a first connection metal layer. The flexible dielectric layer includes a through hole extending along a thickness direction of the flexible dielectric layer. The through hole includes a middle basic hole and outer auxiliary holes. Two or more outer auxiliary holes are distributed and arranged along a circumferential direction of the middle basic hole. The middle basic hole is in communication with the two or more outer auxiliary holes. The first connection metal layer is arranged on an inner wall of the through hole and is connected to the flexible dielectric layer. The first connection metal layer includes a middle channel extending along a thickness direction. The pad and the first connection metal layer are soldered by a solder joint, and a part of the solder joint is filled in the middle channel.

In a possible implementation, two or more outer auxiliary holes are evenly distributed along the circumferential direction of the middle basic hole, so that the overall shape of the through hole can be guaranteed to be regular, which is beneficial to improving the force balance of the connection region between the inner wall of the through hole and the first connection metal layer, thereby ensuring the stability of the connection between the inner wall of the through hole and the first connection metal layer.

In a possible implementation, an axis of the outer auxiliary hole and an axis of the middle basic hole are parallel to each other, so that extension directions of the outer auxiliary hole and the middle basic hole are the same, leading to easy machining and manufacturing.

In a possible implementation, the outer auxiliary hole and the middle basic hole are both circular holes, so that they can be easily machined and manufactured through laser ablation or mechanical drilling, thereby reducing possibility that high machining and manufacturing difficulty caused by an irregular shape of the through hole results in a low yield of the flexible dielectric layer.

In a possible implementation, along the thickness direction, orthographic projections of the outer auxiliary holes and an orthographic projection of the middle basic hole intersect to form an intersection point P1, an intersection point P2, an intersection point P3, and an intersection point P4. The axis of the middle basic hole is located inside a region bounded by connecting lines between the intersection point P1, the intersection point P2, the intersection point P3, and the intersection point P4. The axes of the outer auxiliary holes are located outside the region bounded by the connecting lines between the intersection point P1, the intersection point P2, the intersection point P3, and the intersection point P4.

In a possible implementation, the connecting line between the intersection point P1 and the intersection point P3 and the connecting line between the intersection point P2 and the intersection point P4 intersect and have an angle ranging from 15° to 135°.

In a possible implementation, the two outer auxiliary holes are respectively located on two sides of the middle basic hole. The outer auxiliary holes are in communication with the middle basic hole. Axes of the two outer auxiliary holes and an axis of the middle basic hole are all located in the same plane.

In a possible implementation, four outer auxiliary holes are arranged around the axis of the middle basic hole. An inner wall of a through hole formed by four outer auxiliary holes and one middle basic hole has a larger area, so that a contact area between the first connection metal layer and the inner wall of the through hole is further increased, which is beneficial to further increasing the bonding force between the first connection metal layer and the inner wall of the through hole.

In a possible implementation, along the thickness direction, orthographic projections of the outer auxiliary holes and an orthographic projection of the middle basic hole intersect to form an intersection point P1, an intersection point P2, and an intersection point P3. The axis of the middle basic hole is located inside a region bounded by connecting lines between the intersection point P1, the intersection point P2, and the intersection point P3. The axes of the outer auxiliary holes are located outside the region bounded by the connecting lines between the intersection point P1, the intersection point P2, and the intersection point P3.

In a possible implementation, an angle between the connecting line between the intersection point P1 and the intersection point P2 and the connecting line between the intersection point P2 and the intersection point P3 ranges from 15° to 90°.

In a possible implementation, three outer auxiliary holes are arranged around the axis of the middle basic hole.

In a possible implementation, diameters of the outer auxiliary holes are greater than a diameter of the middle basic hole.

In a possible implementation, the diameters of the outer auxiliary holes are equal. The diameters of the outer auxiliary holes are 1.3 times the diameter of the middle basic hole.

In a possible implementation, diameters of the outer auxiliary holes are less than a diameter of the middle basic hole.

In a possible implementation, the diameters of the outer auxiliary holes are equal. The diameters of the outer auxiliary holes are 0.8 times the diameter of the middle basic hole.

In a possible implementation, the flexible circuit board further includes a second connection metal layer and a third connection metal layer. Along the thickness direction, the second connection metal layer and the third connection metal layer are respectively arranged on two sides of the flexible dielectric layer. The second connection metal layer and the third connection metal layer are respectively connected to the first connection metal layer. The second connection metal layer includes a first via in communication with the middle channel. The third connection metal layer includes a second via in communication with the middle channel. The second connection metal layer and the third connection metal layer are respectively connected to the flexible dielectric layer, which, therefore, is beneficial to further increasing the bonding force between the flexible dielectric layer and the solder pin.

In a possible implementation, the flexible dielectric layer includes two insulation substrates. The through hole runs through the two insulation substrates. The flexible circuit board further includes a fourth connection metal layer. The fourth connection metal layer is connected to the first connection metal layer, and the fourth connection metal layer is arranged between the two insulation substrates.

### BRIEF DESCRIPTION OF THE DRAWINGS

FIG. 1 is a schematic structural diagram of an electronic device according to an embodiment of this application;

FIG. 2 is a partial schematic exploded structural view of an electronic device according to an embodiment of this application;

FIG. 3 is a schematic structural diagram of a printed circuit board according to an embodiment of this application;

FIG. 4 is a partial schematic structural diagram of a circuit board assembly in the related art;

FIG. 5 is a partial schematic cross-sectional structural view of a flexible circuit board in the related art;

FIG. 6 is an enlarged view of a position A in FIG. 4;

FIG. 7 is a partial schematic cross-sectional structural view of arranging solder paste on a pad of a printed circuit board;

FIG. 8 is a schematic diagram of a first state in which a printed circuit board, solder paste, and a flexible circuit board are connected;

FIG. 9 is a schematic diagram of a second state in which a printed circuit board, solder paste, and a flexible circuit board are connected;

FIG. 10 is a partial schematic cross-sectional structural view of a connected state between a printed circuit board and a flexible circuit board;

FIG. 11 is a schematic diagram of a flexible dielectric layer and a solder pin being in a separated state;

FIG. 12 is a partial schematic structural diagram of a flexible circuit board according to an embodiment of this application;

FIG. 13 is an enlarged view of a position B in FIG. 12;

FIG. 14 is a partial schematic structural diagram of a flexible dielectric layer according to an embodiment of this application;

FIG. 15 is an enlarged view of a position C in FIG. 14;

FIG. 16 is a partial schematic structural diagram of a flexible dielectric layer according to another embodiment of this application;

FIG. 17 is an enlarged view of a position D in FIG. 16;

FIG. 18 is a partial schematic structural diagram of a flexible dielectric layer according to still another embodiment of this application;

FIG. 19 is a partial schematic structural diagram of a flexible dielectric layer according to still another embodiment of this application;

FIG. 20 is an enlarged view of a position E in FIG. 19;

FIG. 21 is a partial schematic structural diagram of a flexible dielectric layer according to still another embodiment of this application;

FIG. 22 is a partial schematic structural diagram of a flexible dielectric layer according to still another embodiment of this application;

FIG. 23 is a partial schematic structural diagram of a flexible dielectric layer according to still another embodiment of this application;

FIG. 24 is a partial schematic structural diagram of a flexible dielectric layer according to still another embodiment of this application;

FIG. 25 is a partial schematic cross-sectional structural view of a flexible circuit board according to an embodiment of this application;

FIG. 26 is a partial schematic cross-sectional structural view of a flexible circuit board according to another embodiment of this application;

FIG. 27 is a partial schematic cross-sectional structural view of a connected state between the flexible circuit board according to the embodiment shown in FIG. 26 and a printed circuit board;

FIG. 28 is a partial schematic cross-sectional structural view of a flexible circuit board in the related art;

FIG. 29 is a partial schematic cross-sectional structural view of a flexible circuit board according to an embodiment of this application; and

FIG. 30 is a schematic diagram of comparison between hole wall areas of middle channels in different shapes.

### REFERENCE NUMERALS

10. electronic device;
20. display assembly;
30. middle frame;
40. circuit board assembly;
41. printed circuit board; 41a. soldering region; 411. pad; 412. metal wire; 413. stopping portion;
42. flexible circuit board; 42a. bounded region;
421. flexible dielectric layer; 421a. insulation substrate; 4211. through hole; 4211a. outer auxiliary hole; 4211b. middle basic hole;
422. solder pin; 4221. first connection metal layer; 4221a. middle channel; 4222. second connection metal layer; 4222a. first via; 4223. third connection metal layer; 4223a. second via; 4224. fourth connection metal layer;
423. metal trace;
50. rear housing;
60. electronic component;
70. solder paste;
80. solder joint; 81. first connecting portion; 82. connecting column; 83. second connecting portion;
aa. axis
bb. axis;
X. thickness direction;
Y. circumferential direction.

### DETAILED DESCRIPTION OF ILLUSTRATIVE EMBODIMENTS

An electronic device 10 in the embodiments of this application may be referred to as user equipment (user equipment, UE), a terminal (terminal), or the like. For example, the electronic device 10 may be a mobile terminal or a fixed terminal, such as a tablet computer (portable android device, PAD), a personal digital assistant (personal digital assistant, PDA), a handheld device having a wireless communication function, a computing device, an in-vehicle device, a wearable device, a virtual reality (virtual reality, VR) terminal device, an augmented reality (augmented reality, AR) terminal device, a wireless terminal in industrial control (industrial control), a wireless terminal in self driving (self driving), a wireless terminal in remote medical (remote medical), a wireless terminal in a smart grid (smart grid), a wireless terminal in transportation safety (transportation safety), a wireless terminal in a smart city (smart city), or a wireless terminal in a smart home (smart home). A form of the terminal device is not specifically limited in the embodiments of this application.

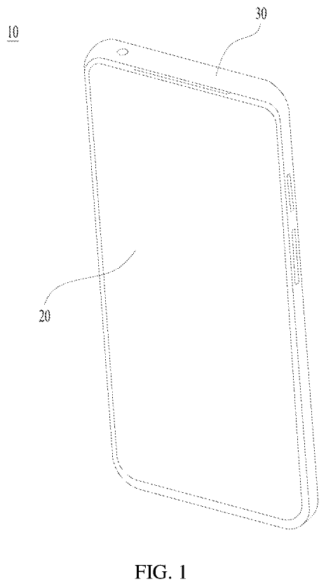

In the embodiments of this application, descriptions are provided by using an example in which the electronic device 10 is a handheld device having a wireless communication function. FIG. 1 schematically shows a structure of the electronic device 10 according to an embodiment. Referring to FIG. 1, the handheld device having a wireless communication function may be, for example, a mobile phone.

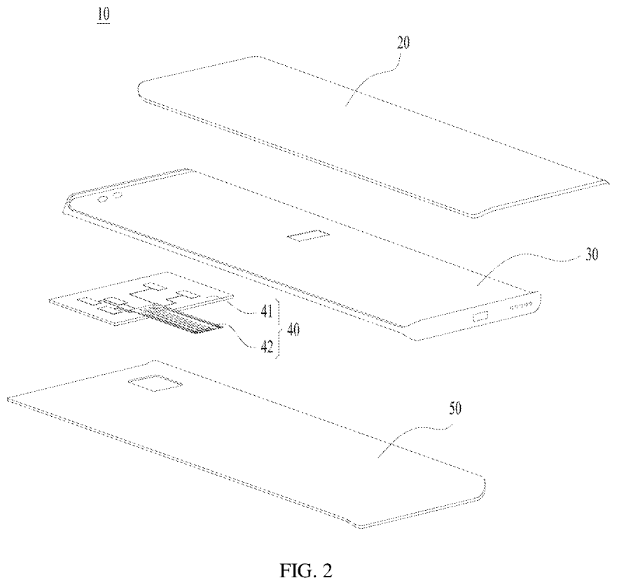

FIG. 2 schematically shows a partial exploded structure of the electronic device 10 according to an embodiment. Referring to FIG. 1 and FIG. 2, the electronic device 10 of the embodiments of this application includes a display assembly 20, a middle frame 30, a circuit board assembly 40, and a rear housing 50. The display assembly 20 includes a display region configured to display image information. The display region of the display assembly 20 faces away from the middle frame 30. In a powered state, the display region can display corresponding image information. The middle frame 30 is arranged between the display assembly 20 and the rear housing 50 along a thickness direction of the electronic device 10. It should be noted that the thickness direction of the electronic device 10 refers to an arrangement direction of the display assembly 20 and the rear housing 50. The circuit board assembly 40 is arranged in a space formed between the middle frame 30 and the rear housing 50, and is located on an inner side of the display assembly 20, so that a user is unlikely to observe the circuit board assembly 40 outside the electronic device 10. The circuit board assembly 40 may be arranged on a surface of the middle frame 30 facing toward the rear housing 50.

The circuit board assembly 40 includes a printed circuit board 41 (Printed Circuit Board, PCB) and a flexible circuit board 42 (Flexible Printed Circuit, FPC).

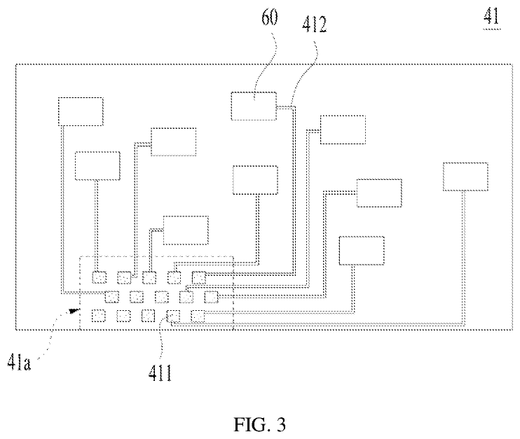

FIG. 3 schematically shows a structure of the printed circuit board 41. Referring to FIG. 3, the printed circuit board 41 may be a single-side board or a double-side board. The single-side board means that electronic components 60 are arranged on one side of the printed circuit board 41. The double-side board means that electronic components 60 are arranged on both sides of the printed circuit board 41. The printed circuit board 41 may be a radio frequency (radio frequency, RF) board or an application processor (application processor, AP) board. The radio frequency board may be configured to carry a radio frequency chip (radio frequency integrated circuit, RFIC), a radio frequency power amplifier (radio frequency power amplifier, RFPA), a wireless fidelity (wireless fidelity, WIFI) chip, and the like, but is not limited thereto. The application processor board, for example, may be configured to carry a system on chip (system on chip, SOC) element, a double data rate (double data rate, DDR) memory, a primary power supply management chip (power management unit, PMU), a secondary power supply management chip, and the like, but is not limited thereto.

The flexible circuit board 42 is configured to connect to functional modules and the corresponding electronic components 60 on the printed circuit board 41. For example, the flexible circuit board 42 can connect to a camera module and a graphics processing chip on the printed circuit board 41. Alternatively, the flexible circuit board 42 can connect to the display assembly 20 and a display and operating chip on the printed circuit board 41. To reduce the volume of the circuit board assembly 40 including the printed circuit board 41 and the flexible circuit board 42, the flexible circuit board 42 is directly connected to the printed circuit board 41, so that use of board-to-board connectors can be canceled. For example, the flexible circuit board 42 is connected to the printed circuit board 41 in a soldering manner.

A soldering region 41a is arranged on a side of the printed circuit board 41. A plurality of pads 411 are arranged in the soldering region 41a. The pads 411 of the printed circuit board 41 are electrically connected to the electronic components 60 arranged on the printed circuit board 41 through metal wires 412 on the printed circuit board 41. For example, materials of the metal wire 412 and the pad 411 may be, but are not limited to, copper or a copper alloy.

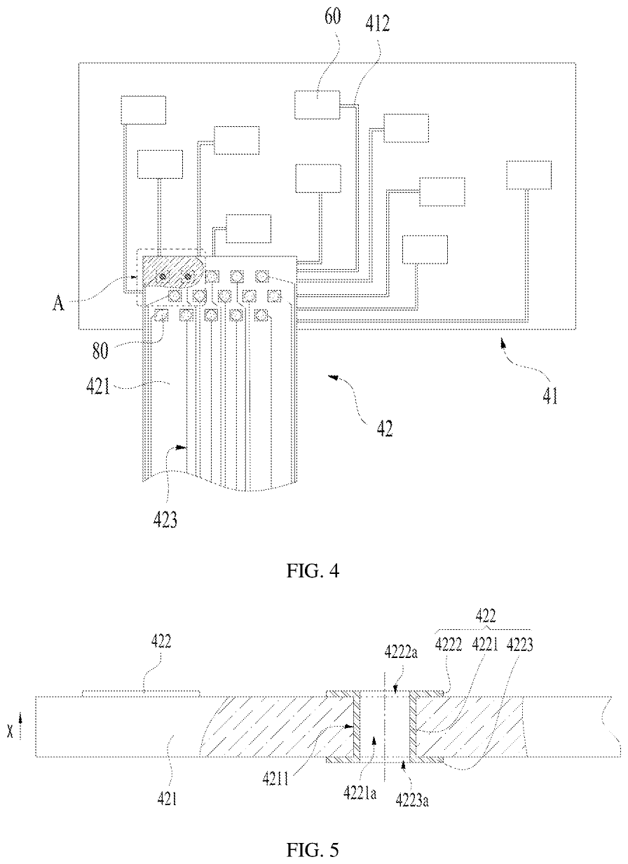

FIG. 4 schematically shows a structure of a circuit board assembly 40. FIG. 5 schematically shows a partial structure of a flexible circuit board 42 according to an embodiment. Referring to FIG. 4 and FIG. 5, the flexible circuit board 42 includes a flexible dielectric layer 421, solder pins 422, and metal traces 423. The flexible dielectric layer 421 may be a layer structure with an insulation function. The flexible dielectric layer 421 is configured to maintain an insulation state between the metal traces 423 or the solder pins 422. The material of the flexible dielectric layer 421 includes, but is not limited to, polyimide (Polyimide, PI), thermoplastic polyimide (Thermoplastic polyimide, TPI), polyester (Polyethylene terephthalate, PET). The flexible dielectric layer 421 has good flexibility, and therefore, can bend when being subjected to an external force. A value of the thickness of the flexible dielectric layer 421 ranges from 0.05 mm to 0.5 mm, and for example, may be, but is not limited to, 0.05 mm, 0.075 mm, 0.1 mm, 0.11 mm, 0.2 mm, 0.3 mm, 0.4 mm, and 0.5 mm. The solder pins 422 and the metal traces 423 are all arranged in the flexible dielectric layer 421. The flexible circuit board 42 includes a plurality of metal traces 423 and a plurality of solder pins 422. The plurality of solder pins 422 are usually arranged in a region in a centralized manner, and the plurality of solder pins 422 are arranged in a plurality of columns. Different metal traces 423 are connected to corresponding solder pins 422. The flexible circuit board 42 is soldered and connected to the corresponding pads 411 on the printed circuit board 41 by the solder pins 422, so that conduction between the flexible circuit board 42 and the printed circuit board 41 is implemented. For example, materials of the solder pin 422 and the metal trace 423 may be, but are not limited to, copper or a copper alloy.

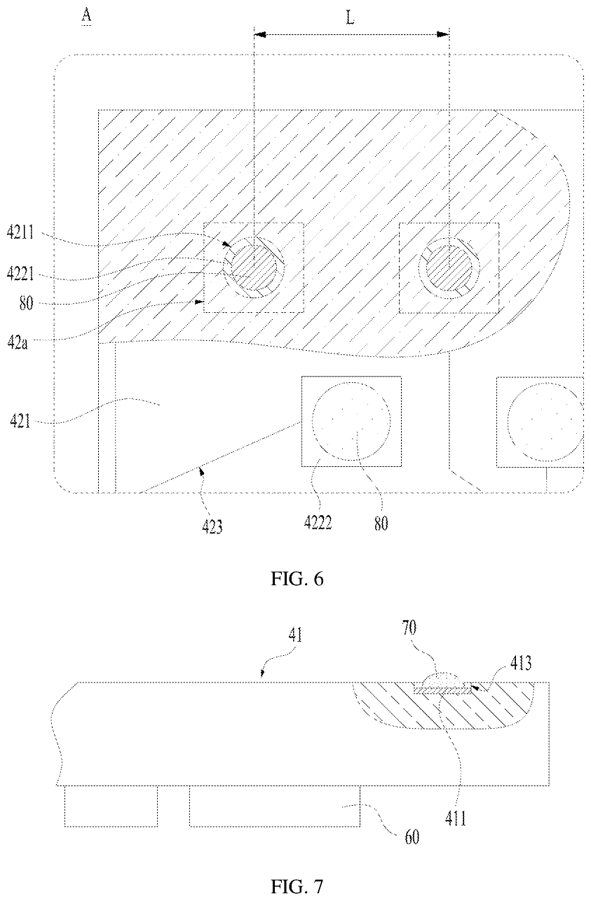

Referring to FIG. 4 to FIG. 6, in the related art, the flexible dielectric layer 421 of the flexible circuit board 42 is provided with a through hole 4211. For example, the through hole 4211 may be a circular hole. Along a thickness direction X of the flexible dielectric layer 421, the flexible dielectric layer 421 includes two opposite surfaces, and the through holes 4211 run through the two surfaces of the flexible dielectric layer 421. For example, the through holes 4211 may be formed on the flexible dielectric layer 421 through laser ablation or mechanical drilling. A quantity of the through holes 4211 is equal to a quantity of the solder pins 422. In each column of through holes 4211, a predetermined distance L needs to be maintained between two neighboring through holes 4211. For example, the predetermined distance L may be 0.6 mm. The solder pin 422 includes a first connection metal layer 4221. The first connection metal layer 4221 is arranged on an inner wall of the through hole 4211 and is connected to the flexible dielectric layer 421. For example, the first connection metal layer 4221 is formed on the inner wall of the through hole 4211 of the flexible dielectric layer 421 through electroless plating. The first connection metal layer 4221 is connected to the flexible dielectric layer 421, and there is a predetermined bonding force therebetween. It should be noted that the bonding force refers to an acting force that needs to overcome when the first connection metal layer 4221 is separated from the flexible dielectric layer 421. An acting force needed to separate the first connection metal layer 4221 from the flexible dielectric layer 421 may be a tensile stress that is applied to the flexible dielectric layer 421 along a radial direction of the through hole 4211, that is in a direction away from the first connection metal layer 4221, and that is needed when the first connection metal layer 4221 is separated from the flexible dielectric layer 421. The first connection metal layer 4221 includes a middle channel 4221a extending along the thickness direction X of the flexible dielectric layer 421. The predetermined distance L between the two neighboring through holes 4211 refers to a vertical distance between axes of the neighboring through holes 4211. For example, the shape of the middle channel 4221a is the same as the shape of the through hole 4211. That is, the middle channel 4221a may be a circular hole. The maximum size of a cross section of the middle channel 4221a is a diameter of the middle channel 4221a. The diameter of the middle channel 4221a may be, but is not limited to, 0.15 mm, 0.2 mm, or 0.4 mm.

It should be noted that if a predetermined quantity of pads 411 are arranged on the printed circuit board 41, a same quantity of solder pins 422 also need to be arranged on the flexible circuit board 42. One solder pin 422 is arranged in correspondence to one pad 411. For example, if 30 pads 411 are arranged on the printed circuit board 41, 30 solder pins 422 also need to be arranged on the flexible circuit board 42. If a predetermined distance L between two neighboring through holes 4211 changes, a distance between neighboring two solder pins 422 also changes. As a result, the solder pins 422 on the flexible circuit board 42 cannot be aligned with the pads 411 on the printed circuit board 41. When the solder pin 422 cannot be aligned with and soldered to the pad 411 on the printed circuit board 41, a quality deviation of soldering between the solder pin 422 and the pad 411 may be caused, and a connection force after the soldering is relatively small. It should be noted that the connection force refers to an acting force that needs to overcome when the solder pin 422 is separated from the pad 411. An acting force needed to separate the solder pin 422 from the pad 411 may be a tensile stress that is applied to the solder pin 422 along a radial direction of the through hole 4211, that is in a direction away from the pad 411, and that is needed when the solder pin 422 is separated from the pad 411. For one flexible circuit board 42, because a predetermined distance L between two neighboring through holes 4211 is fixed, an area occupied by each through hole 4211 is limited. For example, the flexible circuit board 42 is divided into a corresponding quantity of bounded regions 42a, and one through hole 4211 is arranged in correspondence to each bounded region 42a.

FIG. 7 to FIG. 10 schematically show a process of connecting the flexible circuit board 42 and the printed circuit board 41. In some feasible manners, the process of connecting the flexible circuit board 42 and the printed circuit board 41 is as follows:

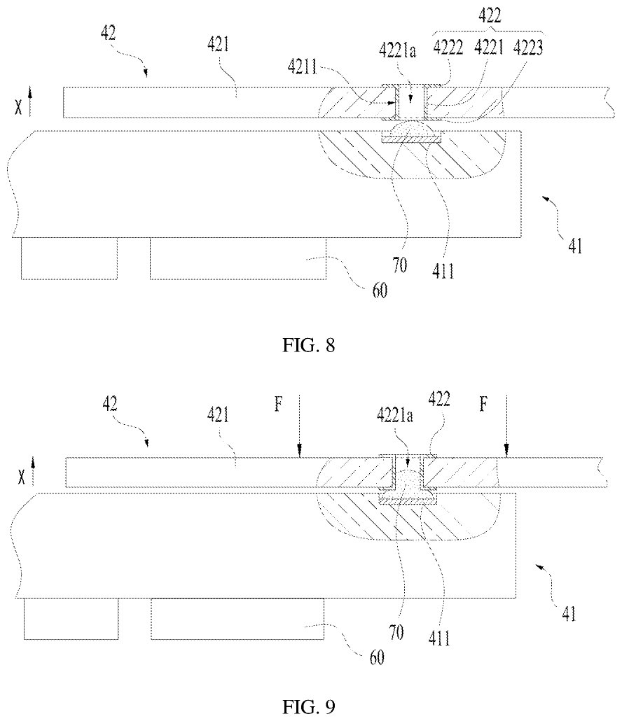

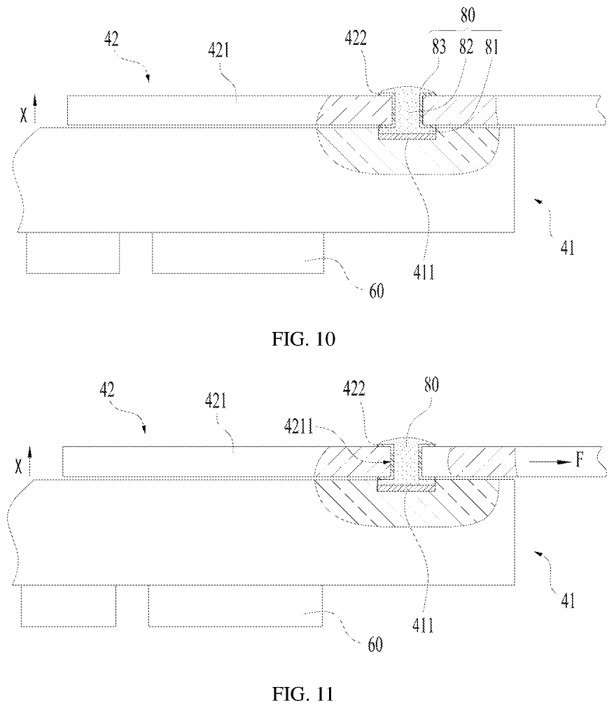

Referring to FIG. 7, solder paste 70 is printed on the pads 411 on the printed circuit board 41 in advance. For example, the solder paste 70 may include metal tin and solder flux. Referring to FIG. 8, the solder pins 422 of the flexible circuit board 42 are made come into contact with the corresponding pads 411 of the printed circuit board 41 through the solder paste 70. Referring to FIG. 9, on a side of the flexible circuit board 42 facing away from the pads 411, a compressive stress toward the pads 411 is applied onto a region on the flexible circuit board 42 in which solder pins 422 are arranged. The solder paste 70 between the solder pins 422 and the corresponding pads 411 is heated. For example, the solder paste 70 is heated by laser. The solder paste 70 melts after absorbing heat. Because the flexible circuit board 42 and the printed circuit board 41 can extrude the melted solder paste 70, a part of the melted solder paste 70 enters the middle channel 4221a of the first connection metal layer 4221. The solder paste 70 rises in the middle channel 4221a of the first connection metal layer 4221 along the thickness direction X of the flexible dielectric layer 421. Referring to FIG. 10, after the solder paste 70 is cured, the solder paste 70 forms solder joints 80, so that the solder pins 422 of the flexible circuit board 42 are connected to the corresponding pads 411 of the printed circuit board 41 by the solder joints 80 and implement conduction.

For example, the solder paste 70 rises in the middle channel 4221a of the first connection metal layer 4221 along the thickness direction X of the flexible dielectric layer 421, and overflows from an opening of the middle channel 4221a facing away from the pad 411. The overflowing solder paste 70 can cover the opening of the middle channel 4221a facing away from the pad 411.

For example, a size of the pad 411 of the printed circuit board 41 is greater than a size of an opening of the middle channel 4221a of the first connection metal layer 4221 facing toward the pad 411. The solder paste 70 between the solder pin 422 of the flexible circuit board 42 and the corresponding pad 411 of the printed circuit board 41 can cover the opening of the middle channel 4221a facing toward the pad 411. Referring to FIG. 7, a stopping portion 413 can be arranged around the pad 411 of the printed circuit board 41. The stopping portion 413 is configured to stop the melted solder paste 70 from flowing to a region outside the pad 411. The flexible circuit board 42 comes into contact with the stopping portion 413, so that a gap is formed between the solder pin 422 of the flexible circuit board 42 and the corresponding pad 411 of the printed circuit board 41. The gap may be configured to accommodate the solder paste 70, to reduce the possibility that the melted solder paste 70 is extruded between the solder pin 422 and the corresponding pad 411, thereby reducing the possibility that a connection force between the solder pin 422 and the corresponding pad 411 after the soldering is completed is relatively small due to a relatively small remaining amount of the solder paste 70 between the solder pin 422 and the corresponding pad 411.

After the solder pins 422 of the flexible circuit board 42 and the corresponding pads 411 of the printed circuit board 41 are connected by the solder joints 80, the bonding force between the solder pins 422 and the solder joints 80 and the bonding force between the solder joints 80 and the corresponding pads 411 are greater than the bonding force between the first connection metal layer 4221 and the flexible dielectric layer 421. During assembly of the circuit board assembly 40 and other parts, there is a case that the flexible dielectric layer 421 is subjected to external tensile force. FIG. 11 schematically shows a separated state of the flexible dielectric layer 421 and the first connection metal layer 4221. Referring to FIG. 11, when a tensile force to which the flexible dielectric layer 421 is subjected is greater than a bonding force between the flexible dielectric layer 421 and the first connection metal layer 4221, the flexible dielectric layer 421 and the first connection metal layer 4221 may be disconnected and separated. As a result, the flexible dielectric layer 421 and the first connection metal layer 4221 are torn, causing the flexible circuit board 42 to fail and be scrapped due to damage, and further causing the circuit board assembly 40 to be scrapped.

The flexible circuit board 42 of the embodiments of this application can increase the bonding force between the flexible dielectric layer 421 and the first connection metal layer 4221, so that the flexible dielectric layer 421 can bear a larger tensile force, which is beneficial to reducing the possibility that the flexible dielectric layer 421 is disconnected and separated from the first connection metal layer 4221 due to a tensile force borne by the flexible dielectric layer 421.

The implementation of the flexible circuit board 42 provided in the embodiments of this application is described below.

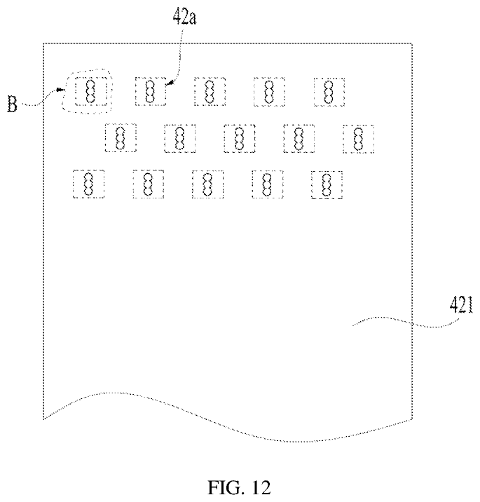

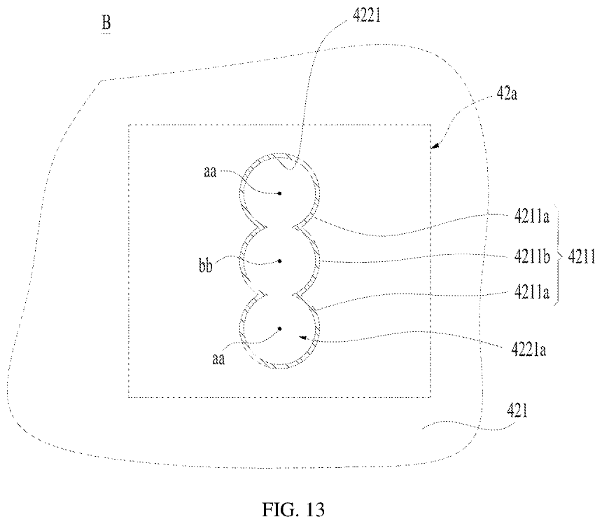

FIG. 12 schematically shows a partial structure of a flexible circuit board 42 according to an embodiment. Referring to FIG. 12 and FIG. 13, the embodiments of this application provide a flexible circuit board 42. The flexible circuit board 42 includes a flexible dielectric layer 421 and a first connection metal layer 4221. The flexible dielectric layer 421 is connected to the first connection metal layer 4221. The flexible dielectric layer 421 has a predetermined thickness. The flexible dielectric layer 421 includes through holes 4211. The flexible dielectric layer 421 includes two opposite surfaces in a thickness direction thereof. One opening of the through hole 4211 is located on one surface of the flexible dielectric layer 421, and another opening thereof is located on the other surface of the flexible dielectric layer 421. The through holes 4211 include outer auxiliary holes 4211a and a middle basic hole 4211b. Two or more outer auxiliary holes 4211a are distributed and arranged along a circumferential direction Y of the middle basic hole 4211b. The middle basic hole 4211b is in communication with the two or more outer auxiliary holes 4211a. The first connection metal layer 4221 is arranged on an inner wall of the through hole 4211 and is connected to the flexible dielectric layer 421. A contour of an outer peripheral surface of the first connection metal layer 4221 facing the inner wall of the through hole 4211 matches a contour of the inner wall of the through hole 4211, and the outer peripheral surface keeps in contact with the inner wall. The first connection metal layer 4221 includes a middle channel 4221a extending along a thickness direction X.

It should be noted that the circumferential direction Y of the middle basic hole 4211b refers to a direction of surrounding the axis of the middle basic hole 4211b. The flexible circuit board 42 according to the embodiments of this application includes a flexible dielectric layer 421 and a first connection metal layer 4221. The flexible dielectric layer 421 is provided with a through hole 4211. The through holes 4211 include outer auxiliary holes 4211a and a middle basic hole 4211b. Compared with an embodiment in the related art in which the through hole 4211 is a single circular hole, since the two or more outer auxiliary holes 4211a are arranged along the circumferential direction Y of the middle basic hole 4211b, a shape of the through hole 4211 is different from a shape of a circular hole. In this application, a manner in which the through hole 4211 is arranged as the outer auxiliary holes 4211a and the middle basic hole 4211b can increase the contact area between the first connection metal layer 4221 and the flexible dielectric layer 421 relatively in the bounded region 42a, which, therefore, is beneficial to increasing the bonding force between the first connection metal layer 4221 and the flexible dielectric layer 421. Therefore, in the embodiments of this application, the bonding force between the first connection metal layer 4221 and the flexible dielectric layer 421 is greater than the bonding force between the first connection metal layer 4221 and the flexible dielectric layer 421 when the through hole 4211 is a circular hole, so that a joint between the flexible dielectric layer 421 and the first connection metal layer can bear a larger tensile force. In the embodiments of this application, the flexible circuit board 42 is connected to the printed circuit board 41, and when the flexible dielectric layer 421 is subjected to a tensile force during assembly, the flexible dielectric layer 421 and the first connection metal layer 4221 are unlikely to be separated, thereby helping to reduce the possibility that the flexible dielectric layer 421 and the first connection metal layer 4221 are disconnected and torn.

Referring to FIG. 13, a cross-sectional shape of the middle channel 4221a of the first connection metal layer 4221 is the same as a cross-sectional shape of the through hole 4211. In some examples, the first connection metal layer 4221 is evenly arranged on an inner wall of the through hole 4211, so that along a direction perpendicular to the inner wall, thickness of positions of the first connection metal layer 4221 are equal.

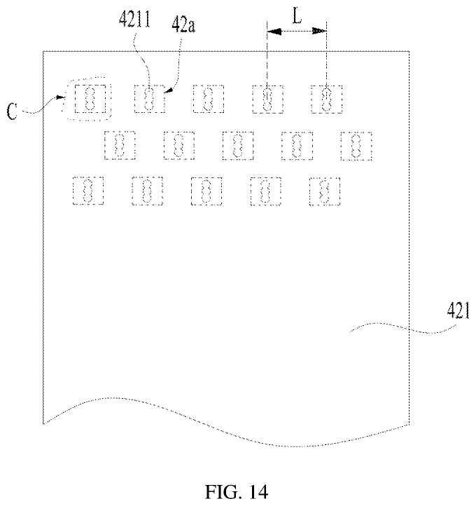

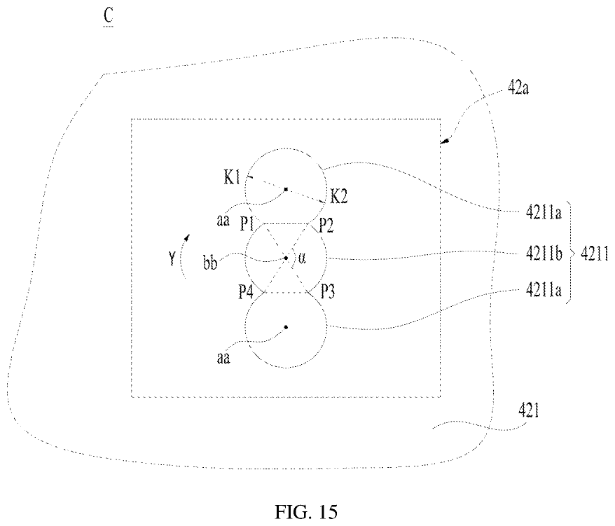

FIG. 14 schematically shows a partial structure of a flexible dielectric layer 421 according to an embodiment. Referring to FIG. 14 and FIG. 15, the flexible circuit board 42 includes a plurality of rows of through holes 4211. In each row of through holes 4211, a predetermined distance L between the two neighboring through holes 4211 refers to a vertical distance between axes bb of two neighboring middle basic holes 4211b.

For one through hole 4211, two or more outer auxiliary holes 4211a are evenly distributed along the circumferential direction Y of the middle basic hole 4211b, so that the overall shape of the through hole 4211 can be guaranteed to be regular, which is beneficial to improving the force balance of the connection region between the inner wall of the through hole 4211 and the first connection metal layer 4221, thereby ensuring the stability of the connection between the inner wall of the through hole 4211 and the first connection metal layer 4221. In the embodiments of this application, an axis aa of the outer auxiliary hole 4211a and the axis bb of the middle basic hole 4211b are spaced apart. The respective axes of the outer auxiliary hole 4211a and the middle basic hole 4211b are parallel to each other, so that extension directions of the outer auxiliary hole 4211a and the middle basic hole 4211b are the same, leading to easy machining and manufacturing. For example, the outer auxiliary hole 4211a and the middle basic hole 4211b are both straight through holes.

In some examples, the outer auxiliary hole 4211a and the middle basic hole 4211b are both circular holes, so that they can be easily machined and manufactured through laser ablation or mechanical drilling, thereby reducing possibility that high machining and manufacturing difficulty caused by an irregular shape of the through hole 4211 results in a low yield of the flexible dielectric layer 421. When the two or more outer auxiliary holes 4211a are uniformly distributed along the circumferential direction Y of the middle basic hole 4211b, axes of the two or more outer auxiliary holes 4211a are located on the same circular trajectory. An axis of the circular trajectory coincides with the axis of the middle basic hole 4211b.

Referring to FIG. 15, two outer auxiliary holes 4211a are distributed along the circumferential direction Y of the middle basic hole 4211b. A machining process of the through hole 4211 may be machining and forming the middle basic hole 4211b in advance on the flexible dielectric layer 421, and then using the middle basic hole 4211b as a basis to machine and form the outer auxiliary holes 4211a. Because there is an intersection region between the outer auxiliary hole 4211a and the middle basic hole 4211b, when the outer auxiliary hole 4211a is machined and formed, at least a part of the inner wall of the middle basic hole 4211b is removed, so that when the completely machined through hole 4211 is observed, the respective inner walls of the middle basic hole 4211b and the outer auxiliary hole 4211a are both broken and discontinuous on the connecting line between the intersection points. For example, two outer auxiliary holes 4211a are evenly distributed along the circumferential direction Y of the middle basic hole 4211b. The middle basic hole 4211b is located between the two outer auxiliary holes 4211a. Respective axes of the two outer auxiliary holes 4211a and the middle basic hole 4211b are all located in the same plane. Arrangement directions of the two outer auxiliary holes 4211a and the middle basic hole 4211b may be perpendicular to an arrangement direction of each row of through holes 4211.

Orthographic projections of the two outer auxiliary holes 4211a and an orthographic projection of the middle basic hole 4211b intersect to form an intersection point P1, an intersection point P2, an intersection point P3, and an intersection point P4. The axis of the middle basic hole 4211b is located inside a region bounded by connecting lines between the intersection point P1, the intersection point P2, the intersection point P3, and the intersection point P4, and the axes of the outer auxiliary holes 4211a are located outside the region bounded by the connecting lines between the intersection point P1, the intersection point P2, the intersection point P3, and the intersection point P4. The region bounded by the connecting lines between the intersection point P1, the intersection point P2, the intersection point P3, and the intersection point P4 is quadrilateral, for example, trapezoidal or rectangular. There are two intersection points between an orthographic projection of one outer auxiliary hole 4211a and the orthographic projection of the middle basic hole 4211b, that is, the intersection point P1 and the intersection point P2. There are two intersection points between an orthographic projection of the outer auxiliary hole 4211a and the orthographic projection of the middle basic hole 4211b, that is, the intersection point P3 and the intersection point P4. An axis aa of one outer auxiliary hole 4211a and the axis bb of the middle basic hole 4211b are respectively located on two sides of the connecting line between the intersection point P1 and the intersection point P2. An axis aa of the other outer auxiliary hole 4211a and the axis bb of the middle basic hole 4211b are respectively located on two sides of the connecting line between the intersection point P3 and the intersection point P4. A length of the connecting line between the intersection point P1 and the intersection point P2 may be less than a diameter of either the outer auxiliary hole 4211a or the middle basic hole 4211b, and a length of the connecting line between the intersection point P3 and the intersection point P4 may also be less than the diameter of either the outer auxiliary hole 4211a or the middle basic hole 4211b.

Because the outer auxiliary holes 4211a are in communication with the middle basic hole 4211b, the respective inner walls of the outer auxiliary holes 4211a and the middle basic hole 4211b are broken and discontinuous in a region between the intersection point P1 and the intersection point P2 and between the intersection point P3 and the intersection point P4.

The connecting line between the intersection point P1 and the intersection point P3 and the connecting line between the intersection point P2 and the intersection point P4 intersect and have an angle α ranging from 15° to 135°. For example, the connecting line between the intersection point P1 and the intersection point P3 and the connecting line between the intersection point P2 and the intersection point P4 intersect and have an angle α ranging from 30° to 90°. For example, the angle α may be, but is not limited to, 30°, 45°, 50°, 60°, 70°, 80°, or 90°.

For example, referring to FIG. 15, diameters of the two outer auxiliary holes 4211a are the same. The diameter of the outer auxiliary holes 4211a is the same as the diameter of the middle basic hole 4211b. In this example, for the convenience of description, the through hole 4211 formed by the outer auxiliary holes 4211a and the middle basic hole 4211b is referred to as a first-type hole. The two outer auxiliary holes 4211a may be arranged symmetrically with respect to the axis of the middle basic hole 4211b, to help balance a bonding force between an inner wall of one outer auxiliary hole 4211a and the first connection metal layer 4221 and a bonding force between an inner wall of the other outer auxiliary hole 4211a and the first connection metal layer 4221. A value of the diameter of the middle basic hole 4211b may range from 0.05 mm to 0.5 mm, for example, may be, but is not limited to, 0.12 mm. A vertical distance between the axis aa of the outer auxiliary hole 4211a and the axis bb of the middle basic hole 4211b is greater than a radius of the middle basic hole 4211b. It should be noted that in this embodiment, the diameter of the outer auxiliary hole 4211a refers to a length of a connecting line between K1 and K2. The diameter of the middle basic hole 4211b refers to a length of the connecting line between the intersection point P1 and the intersection point P3 or a length of the connecting line between the intersection point P2 and the intersection point P4.

In this embodiment, a part of the middle basic hole 4211b is located on a side of the connecting line between the intersection point P1 and the intersection point P4 away from the axis bb of the middle basic hole 4211b, and a part of the middle basic hole 4211b is located on a side of the connecting line between the intersection point P2 and the intersection point P3 away from the side of the axis bb of middle basic hole 4211b.

The through hole 4211 in this application may be a straight hole. A depth direction of the through hole 4211 is the same as the thickness direction X of the flexible dielectric layer 421. A manner in which the through hole 4211 is a straight hole makes it easy to machine and manufacture the through hole 4211 through laser ablation or mechanical drilling.

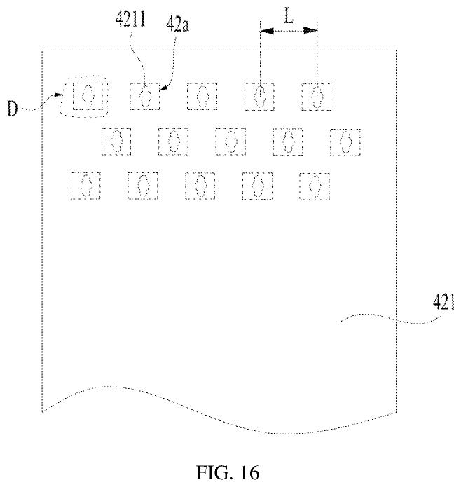

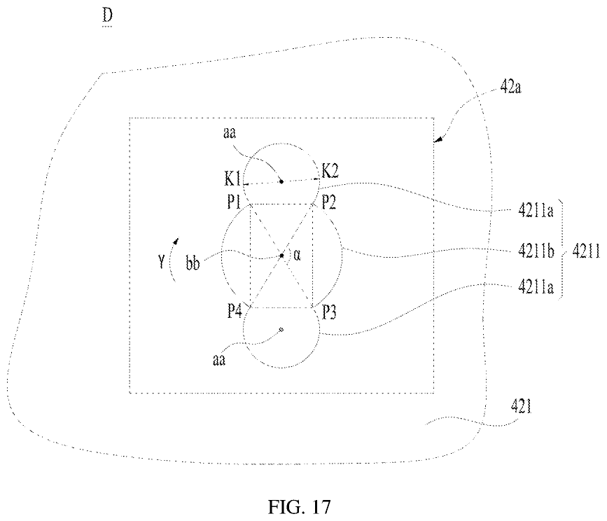

FIG. 16 schematically shows a partial structure of a flexible dielectric layer 421 according to an embodiment. Referring to FIG. 16 and FIG. 17, the same parts between the through hole 4211 in this embodiment and the through hole 4211 of the embodiment shown in FIG. 15 are not described again, and differences are mainly described herein. In this embodiment, the diameters of the two outer auxiliary holes 4211a are both less than the diameter of the middle basic hole 4211b. For the convenience of description, in this embodiment, the through hole 4211 formed by the outer auxiliary holes 4211a and the middle basic hole 4211b is referred to as a second-type hole. For example, a diameter of one outer auxiliary hole 4211a is less than 0.85 times the diameter of the middle basic hole 4211b, and a diameter of the other outer auxiliary hole 4211a is less than 1 times the diameter of the middle basic hole 4211b. The diameters of the two outer auxiliary holes 4211a may be the same. For example, the diameters of the two outer auxiliary holes 4211a are both equal to 0.8 times the diameter of the middle basic hole 4211b. A value of the diameter of the middle basic hole 4211b may range from 0.05 mm to 0.5 mm. For example, the value of the diameter of the middle basic hole 4211b may be, but is not limited to, 0.12 mm.

In some examples, the first connection metal layer 4221 is arranged inside the through hole 4211. A cross-sectional shape of the middle channel 4221a of the first connection metal layer 4221 is the same as a cross-sectional shape of the through hole 4211. In some examples, the first connection metal layer 4221 is evenly arranged on an inner wall of the through hole 4211, so that along a direction perpendicular to the inner wall, thickness of positions of the first connection metal layer 4221 are equal.

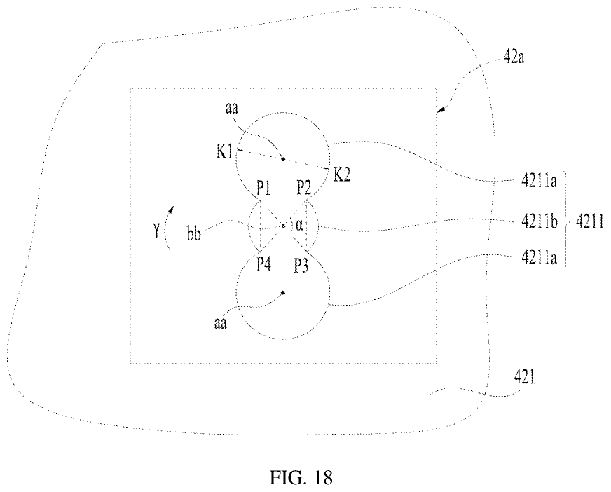

FIG. 18 schematically shows a partial structure of a flexible dielectric layer 421 according to an embodiment. Referring to FIG. 18, the same parts between the through hole 4211 in this embodiment and the through hole 4211 of the embodiment shown in FIG. 15 are not described again, and differences are mainly described herein. In this embodiment, the diameters of the two outer auxiliary holes 4211a are both greater than the diameter of the middle basic hole 4211b. For the convenience of description, in this embodiment, the through hole 4211 formed by the outer auxiliary holes 4211a and the middle basic hole 4211b is referred to as a third-type hole. For example, a diameter of one outer auxiliary hole 4211a is greater than 1.1 times the diameter of the middle basic hole 4211b, and a diameter of the other outer auxiliary hole 4211a is greater than or equal to 1 times the diameter of the middle basic hole 4211b. For example, the diameters of the two outer auxiliary holes 4211a are both equal to 1.3 times the diameter of the middle basic hole 4211b.

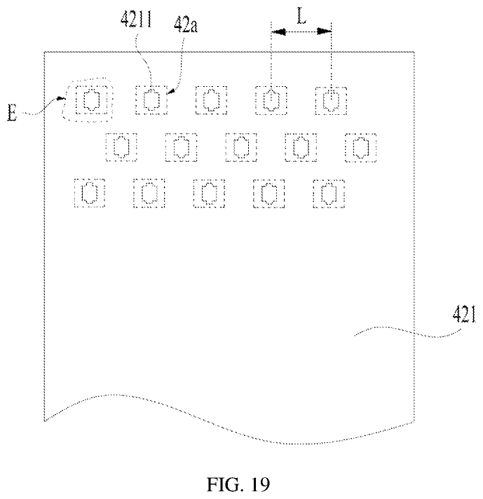

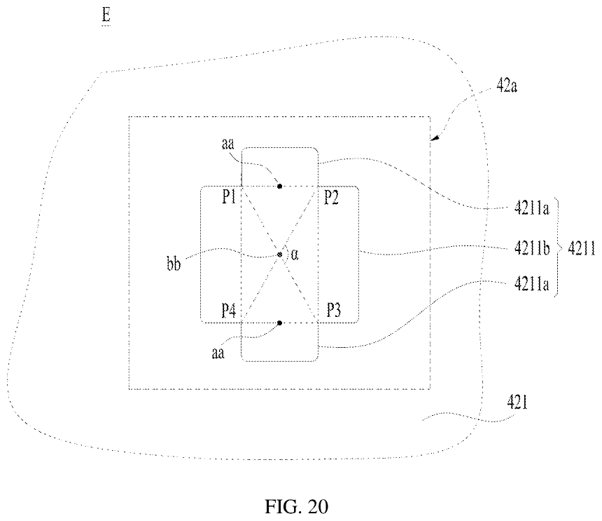

FIG. 19 schematically shows a partial structure of a flexible dielectric layer 421 according to an embodiment. Referring to FIG. 19 and FIG. 20, the outer auxiliary holes 4211a and the middle basic hole 4211b may all be square holes. Sizes of the outer auxiliary holes 4211a are less than a size of the middle basic hole 4211b. A quantity of the outer auxiliary holes 4211a is two. An axis aa of one outer auxiliary hole 4211a may intersect the connecting line between the intersection point P1 and the intersection point P2, and an axis aa of the other outer auxiliary hole 4211a may intersect the connecting line between the intersection point P3 and the intersection point P4. For the convenience of description, in this embodiment, the through hole 4211 formed by the outer auxiliary holes 4211a and the middle basic hole 4211b is referred to as a fourth-type hole.

In some examples, the first connection metal layer 4221 is arranged inside the through hole 4211. A cross-sectional shape of the middle channel 4221a of the first connection metal layer 4221 is the same as a cross-sectional shape of the through hole 4211. In some examples, the first connection metal layer 4221 is evenly arranged on an inner wall of the through hole 4211, so that along a direction perpendicular to the inner wall, thickness of positions of the first connection metal layer 4221 are equal.

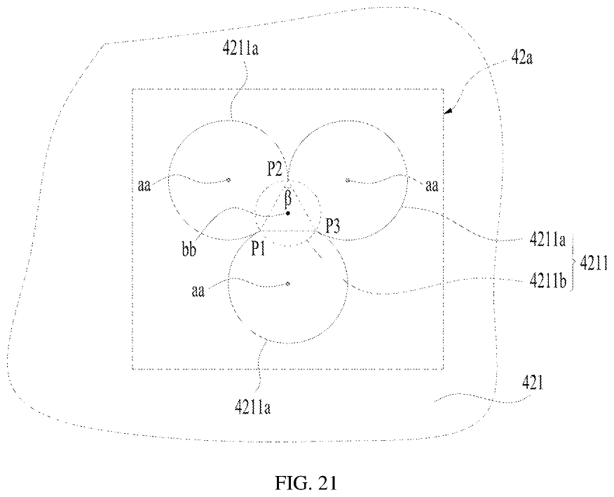

FIG. 21 schematically shows a partial structure of a flexible dielectric layer 421 according to an embodiment. Referring to FIG. 21, in this embodiment, three outer auxiliary holes 4211a are distributed and arranged along the circumferential direction Y of the middle basic hole 4211b. For the convenience of description, in this embodiment, the through hole 4211 formed by the outer auxiliary holes 4211a and the middle basic hole 4211b is referred to as a fifth-type hole. In the bounded region 42a, an inner wall of a through hole 4211 formed by three outer auxiliary holes 4211a and one middle basic hole 4211b has a larger area, so that a contact area between the first connection metal layer 4221 and the inner wall of the through hole 4211 can be increased, which is beneficial to further increasing the bonding force between the first connection metal layer 4221 and the inner wall of the through hole 4211. Orthographic projections of the outer auxiliary holes 4211a and an orthographic projection of the middle basic hole 4211b intersect to form an intersection point P1, an intersection point P2, and an intersection point P3. The axis of the middle basic hole 4211b is located inside a region bounded by connecting lines between the intersection point P1, the intersection point P2, and the intersection point P3, and the axes of the outer auxiliary holes 4211a are located outside the region bounded by the connecting lines between the intersection point P1, the intersection point P2, and the intersection point P3. The region bounded by the connecting lines between the intersection point P1, the intersection point P2, and the intersection point P3 is triangular. For example, an angle β between the connecting line between the intersection point P1 and the intersection point P2 and the connecting line between the intersection point P2 and the intersection point P3 ranges from 15° to 90°. For example, the angle ß may be, but is not limited to, 30°, 45°, 50°, 60°, 70°, 80°, or 90°. The three outer auxiliary holes 4211a can be arranged tangentially, and the intersection point P1, the intersection point P2, and the intersection point P3 are tangent points respectively.

For example, the three outer auxiliary holes 4211a are evenly distributed and arranged along the circumferential direction Y of the middle basic hole 4211b, so that after the first connection metal layer 4221 is connected to the inner wall of the through hole 4211, it is beneficial to ensuring the balance of the bonding forces between the first connection metal layer 4221 and the inner wall of the through hole 4211 in different regions. Respective diameters of the three outer auxiliary holes 4211a may be the same. The diameters of the outer auxiliary holes 4211a are greater than the diameter of the middle basic hole 4211b. For example, the diameters of the three outer auxiliary holes 4211a are all equal to 1.3 times the diameter of the middle basic hole 4211b.

In some other examples, a diameter of one outer auxiliary hole 4211a is greater than 1.1 times the diameter of the middle basic hole 4211b. A diameter of the other outer auxiliary hole 4211a is greater than or equal to 1 times the diameter of the middle basic hole 4211b. A diameter of the other outer auxiliary hole 4211a is greater than or equal to 1.1 times the diameter of the middle basic hole 4211b.

In some examples, the first connection metal layer 4221 is arranged inside the through hole 4211. A cross-sectional shape of the middle channel 4221a of the first connection metal layer 4221 is the same as a cross-sectional shape of the through hole 4211. In some examples, the first connection metal layer 4221 is evenly arranged on an inner wall of the through hole 4211, so that along a direction perpendicular to the inner wall, thickness of positions of the first connection metal layer 4221 are equal.

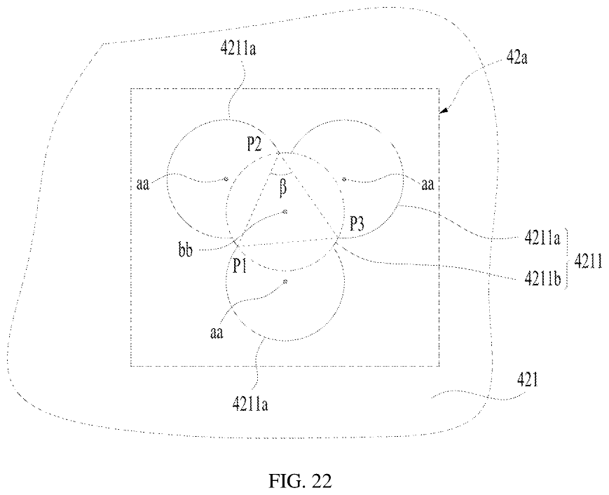

FIG. 22 schematically shows a partial structure of a flexible dielectric layer 421 according to an embodiment. Referring to FIG. 22, the same parts between the through hole 4211 in this embodiment and the through hole 4211 of the embodiment shown in FIG. 21 are not described again, and differences are mainly described herein. Each outer auxiliary hole 4211a in the three outer auxiliary holes 4211a has two intersection points with the middle basic hole 4211b. For the convenience of description, in this embodiment, the through hole 4211 formed by the outer auxiliary holes 4211a and the middle basic hole 4211b is referred to as a sixth-type hole. One intersection point is selected from two intersection points between each outer auxiliary hole 4211a and the middle basic hole 4211b, so that three intersection points are formed, which are respectively an intersection point P1, an intersection point P2, and an intersection point P3. The intersection point P1, the intersection point P2, and the intersection point P3 are spaced apart, and there is one intersection point between the two neighboring ones. The region bounded by the connecting lines between the intersection point P1, the intersection point P2, and the intersection point P3 is triangular. For example, an angle ß between the connecting line between the intersection point P1 and the intersection point P2 and the connecting line between the intersection point P2 and the intersection point P3 ranges from 15° to 90°. For example, the angle may be, but is not limited to, 30°, 45°, 50°, 60°, 70°, 80°, or 90°.

For example, the diameters of the outer auxiliary holes 4211a may be greater than the diameter of the middle basic hole 4211b. Respective diameters of the three outer auxiliary holes 4211a may be the same. For example, the diameters of the three outer auxiliary holes 4211a are all equal to 1.3 times the diameter of the middle basic hole 4211b.

In some other examples, a diameter of one outer auxiliary hole 4211a is greater than 1.1 times the diameter of the middle basic hole 4211b. A diameter of the other outer auxiliary hole 4211a is greater than or equal to 1 times the diameter of the middle basic hole 4211b. A diameter of the other outer auxiliary hole 4211a is greater than or equal to 1.1 times the diameter of the middle basic hole 4211b.

In some other examples, the diameters of the outer auxiliary holes 4211a may be less than the diameter of the middle basic hole 4211b. The diameters of the outer auxiliary holes 4211a are equal, and the diameters of the outer auxiliary holes 4211a are 0.8 times the diameter of the middle basic hole 4211b.

In some examples, the first connection metal layer 4221 is arranged inside the through hole 4211. A cross-sectional shape of the middle channel 4221a of the first connection metal layer 4221 is the same as a cross-sectional shape of the through hole 4211. In some examples, the first connection metal layer 4221 is evenly arranged on an inner wall of the through hole 4211, so that along a direction perpendicular to the inner wall, thickness of positions of the first connection metal layer 4221 are equal.

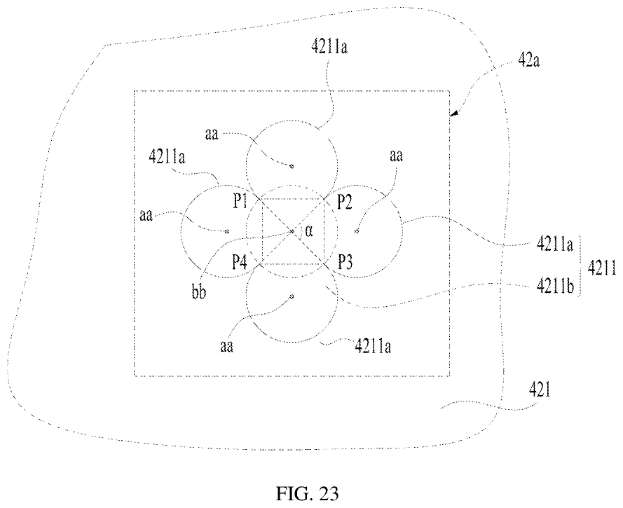

FIG. 23 schematically shows a partial structure of a flexible dielectric layer 421 according to an embodiment. Referring to FIG. 23, in this embodiment, four outer auxiliary holes 4211a are distributed and arranged along the circumferential direction Y of the middle basic hole 4211b. For the convenience of description, in this embodiment, the through hole 4211 formed by the outer auxiliary holes 4211a and the middle basic hole 4211b is referred to as a seventh-type hole. In the bounded region 42a, an inner wall of a through hole 4211 formed by four outer auxiliary holes 4211a and one middle basic hole 4211b has a larger area, so that a contact area between the first connection metal layer 4221 and the inner wall of the through hole 4211 is further increased, which is beneficial to further increasing the bonding force between the first connection metal layer 4221 and the inner wall of the through hole 4211. Orthographic projections of the outer auxiliary holes 4211a and an orthographic projection of the middle basic hole 4211b intersect to form an intersection point P1, an intersection point P2, an intersection point P3, and an intersection point P4. The region bounded by the connecting lines between the intersection point P1, the intersection point P2, the intersection point P3, and the intersection point P4 is quadrilateral, for example, trapezoidal or rectangular. The connecting line between the intersection point P1 and the intersection point P3 and the connecting line between the intersection point P2 and the intersection point P4 intersect and may have an angle α ranging from 15° to 135°. For example, the connecting line between the intersection point P1 and the intersection point P3 and the connecting line between the intersection point P2 and the intersection point P4 intersect and have an angle α ranging from 30° to 90°. For example, the angle α may be, but is not limited to, 30°, 45°, 50°, 60°, 70°, 80°, or 90°. The four outer auxiliary holes 4211a can be arranged tangentially, and the intersection point P1, the intersection point P2, the intersection point P3, and the intersection point P4 are tangent points respectively.

For example, the four outer auxiliary holes 4211a are evenly distributed and arranged along the circumferential direction Y of the middle basic hole 4211b, so that after the first connection metal layer 4221 is connected to the inner wall of the through hole 4211, it is beneficial to ensuring the balance of the bonding forces between the first connection metal layer 4221 and the inner wall of the through hole 4211 in different regions. The diameters of the outer auxiliary holes 4211a are equal to the diameter of the middle basic hole 4211b. Respective diameters of the four outer auxiliary holes 4211a are the same.

In some other examples, a diameter of one outer auxiliary hole 4211a is greater than 1.1 times the diameter of the middle basic hole 4211b. A diameter of another outer auxiliary hole 4211a is greater than or equal to 1 times the diameter of the middle basic hole 4211b. Diameters of the remaining two outer auxiliary holes 4211a are greater than or equal to 1.1 times the diameter of the middle basic hole 4211b.

In some examples, the first connection metal layer 4221 is arranged inside the through hole 4211. A cross-sectional shape of the middle channel 4221a of the first connection metal layer 4221 is the same as a cross-sectional shape of the through hole 4211. In some examples, the first connection metal layer 4221 is evenly arranged on an inner wall of the through hole 4211, so that along a direction perpendicular to the inner wall, thickness of positions of the first connection metal layer 4221 are equal.

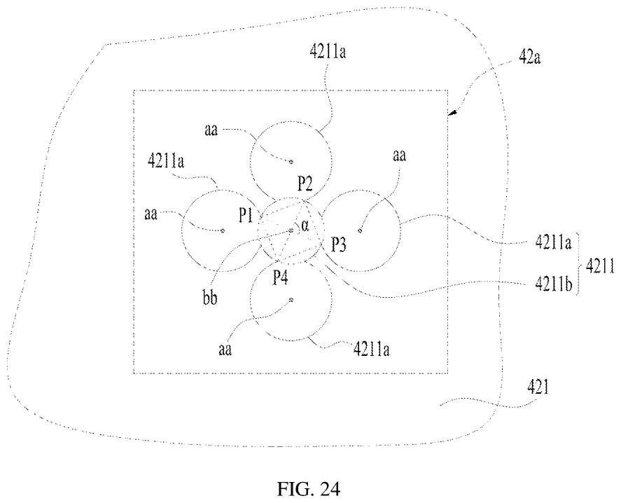

FIG. 24 schematically shows a partial structure of a flexible dielectric layer 421 according to an embodiment. Referring to FIG. 24, the same parts between the through hole 4211 in this embodiment and the through hole 4211 of the embodiment shown in FIG. 23 are not described again, and differences are mainly described herein. In this embodiment, four outer auxiliary holes 4211a are distributed and arranged along the circumferential direction Y of the middle basic hole 4211b. Each outer auxiliary hole 4211a has two intersection points with the middle basic hole 4211b. For the convenience of description, in this embodiment, the through hole 4211 formed by the outer auxiliary holes 4211a and the middle basic hole 4211b is referred to as an eighth-type hole. One intersection point is selected from two intersection points between each outer auxiliary hole 4211a and the middle basic hole 4211b, and four intersection points are respectively an intersection point P1, an intersection point P2, an intersection point P3, and an intersection point P4. The intersection point P1, the intersection point P2, the intersection point P3, and the intersection point P4 are spaced apart, and there is one intersection point between the two neighboring ones. The region bounded by the connecting lines between the intersection point P1, the intersection point P2, the intersection point P3, and the intersection point P4 is quadrilateral, for example, trapezoidal or rectangular.

For example, four outer auxiliary holes 4211a are evenly distributed and arranged along the circumferential direction Y of the middle basic hole 4211b. The four outer auxiliary holes 4211a are spaced apart. The diameters of the outer auxiliary holes 4211a are greater than the diameter of the middle basic hole 4211b. Respective diameters of the four outer auxiliary holes 4211a are the same. For example, the diameters of the four outer auxiliary holes 4211a are all equal to 1.3 times the diameter of the middle basic hole 4211b.

In some other examples, a diameter of one outer auxiliary hole 4211a is greater than 1.1 times the diameter of the middle basic hole 4211b. A diameter of another outer auxiliary hole 4211a is greater than or equal to 1 times the diameter of the middle basic hole 4211b. Diameters of the remaining two outer auxiliary holes 4211a are greater than or equal to 1.1 times the diameter of the middle basic hole 4211b.

In some other examples, the diameters of the outer auxiliary holes 4211a may be less than the diameter of the middle basic hole 4211b. The diameters of the outer auxiliary holes 4211a are equal, and the diameters of the outer auxiliary holes 4211a are 0.8 times the diameter of the middle basic hole 4211b.

In some examples, the first connection metal layer 4221 is arranged inside the through hole 4211. A cross-sectional shape of the middle channel 4221a of the first connection metal layer 4221 is the same as a cross-sectional shape of the through hole 4211. In some examples, the first connection metal layer 4221 is evenly arranged on an inner wall of the through hole 4211, so that along a direction perpendicular to the inner wall, thickness of positions of the first connection metal layer 4221 are equal.

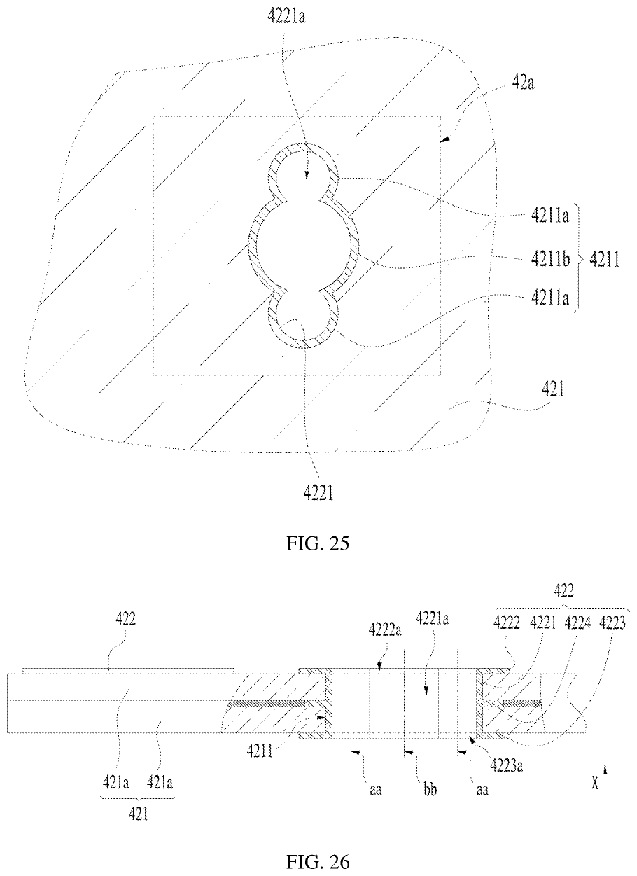

FIG. 25 schematically shows a partial cross-sectional structure of a flexible circuit board 42 according to an embodiment. Referring to FIG. 25, a cross-sectional shape of the middle channel 4221a of the first connection metal layer 4221 is the same as a cross-sectional shape of the through hole 4211. In some examples, the first connection metal layer 4221 is evenly arranged on an inner wall of the through hole 4211, so that along a direction perpendicular to the inner wall, thickness of positions of the first connection metal layer 4221 are equal. A center of the middle channel 4221a of the first connection metal layer 4221 coincides with a center of the through hole 4211, which helps to perform positioning by aligning the center of the middle channel 4221a with the center of the pad 411 on the printed circuit board 41, to ensure that relative positions of the solder pin 422 and the pad 411 satisfy the position precision requirements.

FIG. 26 schematically shows a partial cross-sectional structure of a flexible circuit board 42 according to an embodiment. Referring to FIG. 26, the solder pin 422 of the flexible circuit board 42 further includes a second connection metal layer 4222 and a third connection metal layer 4223. Along the thickness direction, the second connection metal layer 4222 and the third connection metal layer 4223 are respectively arranged on two sides of the flexible dielectric layer 421. The second connection metal layer 4222 and the third connection metal layer 4223 are respectively connected to the first connection metal layer 4221. The second connection metal layer 4222 includes a first via 4222a in communication with the middle channel 4221a. The third connection metal layer 4223 includes a second via 4223a in communication with the middle channel 4221a. The second connection metal layer 4222 is configured to connect to the metal traces 423. For example, the second connection metal layer 4222 has a shape the same as that of the bounded region 42a. Edges of the second connection metal layer 4222 may be aligned with boundaries of the bounded region 42a. After molten solder paste 70 overflows from a side of the flexible dielectric layer 421 facing away from the pad 411, the solder paste 70 flows to a surface of the second connection metal layer 4222 facing away from the pad 411. After being cured, the solder paste 70 is connected to the second connection metal layer 4222. The third connection metal layer 4223 is configured to face toward the pad 411 of the printed circuit board 41 and is soldered to the pad 411. The second connection metal layer 4222 and the third connection metal layer 4223 are respectively connected to the flexible dielectric layer 421, which, therefore, is beneficial to further increasing the bonding force between the flexible dielectric layer 421 and the solder pin 422. A shape of the first via 4222a of the second connection metal layer 4222 and the second via 4223a of the third connection metal layer 4223 are respectively the same as a shape of the middle channel 4221a of the first connection metal layer 4221. For example, the second connection metal layer 4222 is of a circular structure or a rectangular structure. The third connection metal layer 4223 is of a circular structure or a rectangular structure. For example, the second connection metal layer 4222 and the third connection metal layer 4223 are formed through electroless plating.

Referring to FIG. 26, the flexible dielectric layer 421 includes two insulation substrates 421a. The through hole 4211 runs through the two insulation substrates 421a. The solder pin 422 of the flexible circuit board 42 further includes a fourth connection metal layer. The fourth connection metal layer is connected to the first connection metal layer 4221, and the fourth connection metal layer is arranged between the two insulation substrates 421a. The fourth connection metal layer is connected to the flexible dielectric layer 421, which, therefore, is beneficial to further increasing the bonding force between the flexible dielectric layer 421 and the solder pin 422. For example, the first connection metal layer 4221, the second connection metal layer 4222, the third connection metal layer 4223, and the fourth connection metal layer form an integral structure.

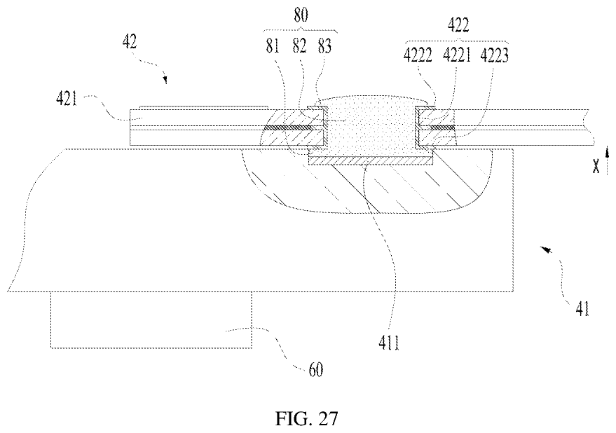

FIG. 27 schematically shows a partial cross-sectional structure of a connected state between the flexible circuit board 42 and the printed circuit board 41 according to an embodiment. Referring to FIG. 27, the molten solder paste 70 forms a solder joint 80 after being cured. The solder joint 80 includes a first connecting portion 81, a connecting column 82, and a second connecting portion 83. The first connecting portion 81 is located between the pad 411 and the flexible dielectric layer 421. The first connecting portion 81 occludes an opening of the middle channel 4221a facing toward the printed circuit board 41. The second connecting portion 83 is located on a side of the flexible dielectric layer 421 facing away from the printed circuit board 41. The second connecting portion 83 occludes an opening of the middle channel 4221a facing away from the printed circuit board 41. The connecting column 82 is located in the middle channel 4221a. The first connecting portion 81 and the second connecting portion 83 are respectively connected to the connecting column 82. The first connecting portion 81 is connected to a surface of the third connection metal layer 4223 facing toward the pad 411. The second connecting portion 83 is connected to the second connection metal layer 4222.

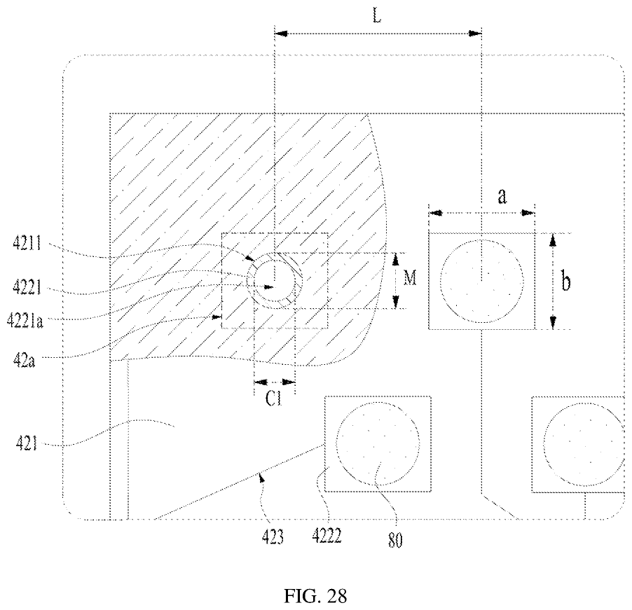

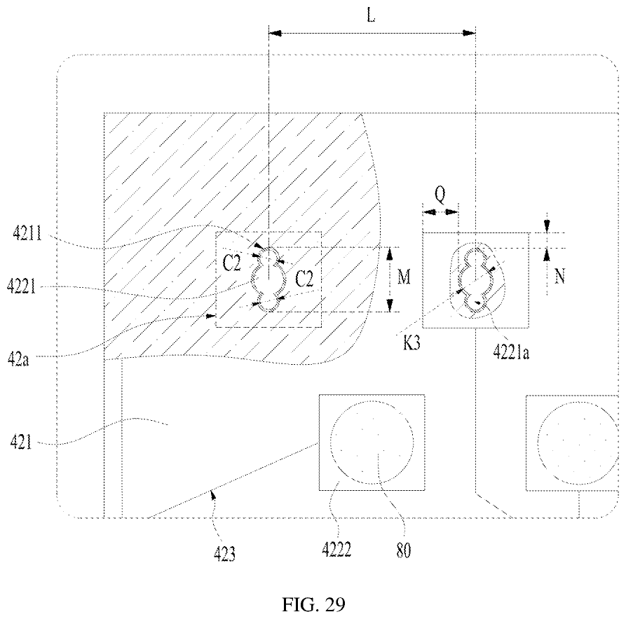

Referring to FIG. 28 and FIG. 29, based on the embodiments of this application, Table 1 exemplifies data for the middle channel 4221a of the first connection metal layer 4221 in the related art being a circular hole, and the middle channel 4221a of the first connection metal layer 4221 in the embodiments of this application being a first-type hole, a second-type hole, and a seventh-type hole.

TABLE 1

| | | L equals | L equals | L equals | L equals |
|---|---|---|---|---|---|
| | | 0.6 mm | 0.6 mm | 0.6 mm | 0.6 mm |
| | | Circular | First-type | Second-type | Seventh-type |
| Property | Name | hole | hole | hole | hole |
| a | Width of second | 0.34 | 0.34 | 0.34 | 0.34 |
| | connection metal | | | | |
| | layer/mm | | | | |
| b | Length of second | 0.46 | 0.46 | 0.46 | 0.46 |
| | connection metal | | | | |
| | layer/mm | | | | |
| C1 | Size of middle | 0.15 | — | — | — |
| | channel/mm | | | | |
| C2 | Sizes corresponding | — | 0.1 | 0.1 | 0.1 |
| | to middle channel | | | | |
| | and outer auxiliary | | | | |
| | hole/mm | | | | |
| K3 | Sizes corresponding | — | 0.1 | 0.24 | — |
| | to middle channel | | | | |
| | and middle basic | | | | |
| | hole/mm | | | | |
| N | Distance from hole | 0.155 | 0.05 | 0.05 | 0.13 |
| | to edge of second | | | | |
| | connection metal | | | | |
| | layer (vertical | | | | |
| | direction)/mm | | | | |
| Q | Distance from hole | 0.095 | 0.12 | 0.05 | 0.07 |
| | to edge of second | | | | |
| | connection metal | | | | |
| | layer (horizontal | | | | |
| | direction)/mm | | | | |
| M | Total length of hole | 0.15 | 0.36 | 0.36 | 0.2 |
| | in vertical | | | | |
| | direction/mm | | | | |

| | | | | |
|---|---|---|---|---|
| Hole wall area of | 0.471*H | 0.613*H | 0.948*H | 0.628*H |
| middle channel | | | | |
| Ranking | 4 | 3 | 1 | 2 |

In Table 1, a parameter H represents an axial direction of the middle channel 4221a, and a depth of the middle channel 4221a is measured. The axial direction of the middle channel 4221a is the same as the thickness direction X of the flexible dielectric layer 421. In Table 1, a depth H of the circular hole, a depth H of the first-type hole, a depth H of the second-type hole, and a depth H of the seventh-type hole have the same value.

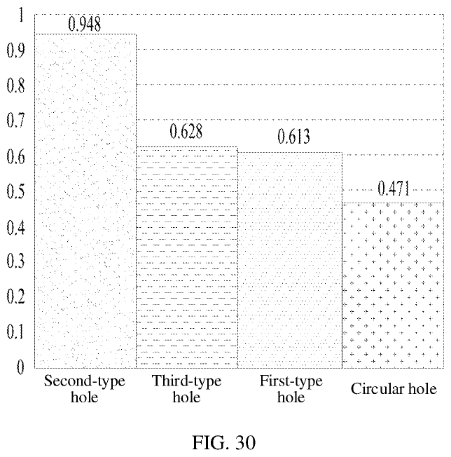

In a case that the width and the length of the second connection metal layer 4222 are the same, different shapes of the middle channel 4221a of the first connection metal layer 4221 may lead to different hole wall areas of the middle channel 4221a. For example, referring to Table 1 and FIG. 30, when the shape of the middle channel 4221a is the circular hole, a hole wall area of the middle channel 4221a is S1. In an embodiment in which the shapes of the middle channel 4221a are the first-type hole, the second-type hole, and the seventh-type hole, hole wall areas of the middle channel 4221a are S2, S3, and S4. S3>S4>S2>S1.

A cross-sectional shape of the middle channel 4221a of the first connection metal layer 4221 is the same as a cross-sectional shape of the through hole 4211. The hole wall area of the middle channel 4221a is positively correlated to the contact area between the first connection metal layer 4221 and the flexible dielectric layer 421. Therefore, in this application, a manner in which the through hole 4211 is arranged as the outer auxiliary holes 4211a and the middle basic hole 4211b can increase the contact area between the first connection metal layer 4221 and the flexible dielectric layer 421 relatively, which, therefore, is beneficial to increasing the bonding force between the first connection metal layer 4221 and the flexible dielectric layer 421.

In the description of the embodiments of this application, it should be noted that, unless specified or limited otherwise, the terms “mount”, “connect”, and “connection” should be understood broadly, for example, which may be fixed connection, indirectly connected to each other through an intermediate medium, or communication inside two elements or an interaction relationship between two elements. A person of ordinary skill in the art may understand the specific meanings of the foregoing terms in the embodiments of this application according to specific situations.

In the embodiments of this application, it is implied that an apparatus or element in question needs to have a particular orientation, or needs to be constructed and operated in a particular orientation, and therefore cannot be construed as a limitation on the embodiments of this application. In the description of the embodiments of this application, unless otherwise exactly and specifically ruled, “a plurality of” means two or more.

The terms such as “first”, “second”, “third”, and “fourth” (if any) in the specification and claims of the embodiments of this application and in the accompanying drawings are used for distinguishing between similar objects and not necessarily used for describing any particular order or sequence. It should to be understood that the data termed in such a way are interchangeable in proper circumstances so that the embodiments of this application described herein can be implemented in orders except the order illustrated or described herein. Moreover, the terms “include”, “comprise”, and any other variants thereof mean are intended to cover the non-exclusive inclusion. For example, a process, method, system, product, or device that includes a list of steps or units is not necessarily limited to those expressly listed steps or units, but may include other steps or units not expressly listed or inherent to such a process, method, product, or device.

“Plurality of” in this specification means two or more. The term “and/or” in this specification describes only an association relationship for describing associated objects and represents that three relationships may exist. For example, A and/or B may represent the following three cases: Only A exists, both A and B exist, and only B exists. In addition, the character “/” in this specification generally indicates an “or” relationship between the associated objects. In a formula, the character “/” indicates a “division” relationship between the associated objects.

It may be understood that, various reference numerals in the embodiments of this application are merely for differentiation for ease of description, and are not intended to limit the scope of the embodiments of this application.

It may be understood that, sequence numbers of the foregoing processes do not mean execution sequences in various embodiments of this application. The execution sequences of the processes should be determined according to functions and internal logic of the processes, and should not be construed as any limitation on the implementation processes of the embodiments of this application.

1. A flexible circuit board, comprising at least:
a flexible dielectric layer, comprising a through hole extending along a thickness direction of the flexible dielectric layer, wherein the through hole comprises a middle basic hole and outer auxiliary holes, two or more outer auxiliary holes are arranged along a circumferential direction of the middle basic hole, and the middle basic hole is in communication with the two or more outer auxiliary holes; and
a first connection metal layer, arranged on the inner wall of the through hole and connected to the flexible dielectric layer, wherein the first connection metal layer comprises a middle channel along the thickness direction.

2. The flexible circuit board according to claim 1, wherein the two or more outer auxiliary holes are evenly distributed along the circumferential direction of the middle basic hole.

3. The flexible circuit board according to claim 1, wherein axes of the outer auxiliary holes are parallel to the axis of the middle basic hole.

4. The flexible circuit board according to claim 1, wherein the middle basic hole and the outer auxiliary holes are all circular holes.

5. The flexible circuit board according to claim 4, wherein orthographic projections of the outer auxiliary holes intersect an orthographic projection of the middle basic hole along the thickness direction, to form an intersection point P1, an intersection point P2, an intersection point P3, and an intersection point P4, wherein
the axis of the middle basic hole is located inside a region bounded by connecting lines between the intersection point P1, the intersection point P2, the intersection point P3, and the intersection point P4, and the axes of the outer auxiliary holes are located outside the region bounded by the connecting lines between the intersection point P1, the intersection point P2, the intersection point P3, and the intersection point P4.

6. The flexible circuit board according to claim 5, wherein the connecting line between the intersection point P1 and the intersection point P3 and the connecting line between the intersection point P2 and the intersection point P4 intersect and have an angle ranging from 15° to 135°.

7. The flexible circuit board according to claim 4, wherein two outer auxiliary holes are respectively located on two sides of the middle basic hole, the outer auxiliary holes are in communication with the middle basic hole, and the axes of the two outer auxiliary hole and the axis of the middle basic hole are located in a same plane; or four outer auxiliary holes are arranged around the axis of the middle basic hole.

8. The flexible circuit board according to claim 4, wherein orthographic projections of the outer auxiliary holes intersect an orthographic projection of the middle basic hole along the thickness direction, to form an intersection point P1, an intersection point P2, and an intersection point P3, the axis of the middle basic hole is located inside a region bounded by connecting lines between the intersection point P1, the intersection point P2, and the intersection point P3, and the axes of the outer auxiliary holes are located outside the region bounded by the connecting lines between the intersection point P1, the intersection point P2, and the intersection point P3.

9. The flexible circuit board according to claim 8, wherein an angle between the connecting line between the intersection point P1 and the intersection point P2 and the connecting line between the intersection point P2 and the intersection point P3 intersect ranges from 15° to 90°.

10. The flexible circuit board according to claim 4, wherein three outer auxiliary holes are arranged around the axis of the middle basic hole.

11. The flexible circuit board according to claim 4, wherein diameters of the outer auxiliary holes are greater than a diameter of the middle basic hole.

12. The flexible circuit board according to claim 11, wherein the diameters of the outer auxiliary holes are equal, and the diameters of the outer auxiliary holes are 1.3 times the diameter of the middle basic hole.

13. The flexible circuit board according to claim 4, wherein diameters of the outer auxiliary holes are less than a diameter of the middle basic hole.

14. The flexible circuit board according to claim 13, wherein the diameters of the outer auxiliary holes are equal, and the diameters of the outer auxiliary holes are 0.8 times the diameter of the middle basic hole.

15. The flexible circuit board according to claim 1, wherein the flexible circuit board further comprises a second connection metal layer and a third connection metal layer, along the thickness direction, the second connection metal layer and the third connection metal layer are respectively arranged on two sides of the flexible dielectric layer, the second connection metal layer and the third connection metal layer are respectively connected to the first connection metal layer, the second connection metal layer comprises a first via in communication with the middle channel, and the third connection metal layer comprises a second via in communication with the middle channel.

16. The flexible circuit board according to claim 15, wherein the flexible dielectric layer comprises two insulation substrates, the through hole run through the two insulation substrates, the flexible circuit board further comprises a fourth connection metal layer, the fourth connection metal layer is connected to the first connection metal layer, and the fourth connection metal layer is arranged between the two insulation substrates.

17. A circuit board assembly, comprising at least:
a printed circuit board, comprising a pad; and
a flexible circuit board comprising at least:
a flexible dielectric layer, comprising a through hole extending along a thickness direction of the flexible dielectric layer, wherein the through hole comprises a middle basic hole and outer auxiliary holes, two or more outer auxiliary holes are arranged along a circumferential direction of the middle basic hole, and the middle basic hole is in communication with the two or more outer auxiliary holes; and
a first connection metal layer, arranged on the inner wall of the through hole and connected to the flexible dielectric layer, wherein the first connection metal layer comprises a middle channel along the thickness direction,
wherein the pad and the first connection metal layer are soldered by a solder joint, and a part of the solder joint is filled in the middle channel.

18. An electronic device, comprising at least the circuit board assembly according to claim 17.
